(19) United States
(12) Patent Application Publication
(10) Pub. No.: US 2025/0054785 A1
(43) Pub. Date: Feb. 13, 2025

(54) METHOD OF SELECTIVE RELEASE OF COMPONENTS USING THERMAL RELEASE LAYER

(71) Applicant: Deca Technologies USA, Inc., Tempe, AZ (US)

(72) Inventors: Benedict SAN JOSE, Manila (PH); Clifford SANDSTROM, Richfield, MN (US); Timothy L. OLSON, Phoenix, AZ (US); Paul R. HOFFMAN, San Diego, CA (US)

(21) Appl. No.: 18/794,859

(22) Filed: Aug. 5, 2024

Related U.S. Application Data
(60) Provisional application No. 63/531,540, filed on Aug. 8, 2023.

(51) Int. Cl. H01L 21/67; H01L 21/683; H01L 21/78

(52) U.S. Cl. CPC H01L 21/67132; H01L 21/67144; H01L 21/67248; H01L 21/6836; H01L 21/78; H01L 2221/68322; H01L 2221/68327

(57) ABSTRACT

The disclosure describes a method for transferring components for an electronic assembly. The process involves providing a wafer coupled to an energy activated release layer, and singulating the wafer into multiple components. A portion of the energy activated release layer is then activated, allowing for the removal of a component from the layer. Activation of the energy activated release layer occurs through a change in temperature, not with ultraviolet light. The components are removed without the use of a conventional ejector pin or needle and may be removed using a gang pickup. The change in temperature of the energy activated release layer may be heating or cooling. The change in temperature may be driven from above, below, or both above and below the energy activated release layer, including from a bottom thermal probe that may also act as a temperature changing ejector needle.

### RELATED APPLICATIONS

This application claims the benefit of U.S. provisional patent application 63/531,540, filed Aug. 8, 2023, titled “Method of Selective Release of Components Using Thermal Release Layer”, the entirety of the disclosure of which is hereby incorporated by this reference.

### TECHNICAL FIELD

Embodiments of the disclosure relate to methods of transferring or moving components from a source wafer to a substrate or carrier to form an electronic assembly, and more specifically transferring fragile components which are prone to fracture from a source wafer using thermally activated release layers.

### BACKGROUND

Semiconductor chips, as well as other components, may be moved to a substrate or carrier for further processing as part of the manufacturing process for electronic devices. The components may comprise semiconductor active integrated circuit devices, semiconductor discrete devices, semiconductor passive devices, bridge die, LEDs (Light Emitting Diodes), and other micro-electronic and micro-optoelectronic devices. Further processing may be particularly beneficial for applications that require the assembly of these components onto various substrates, including temporary carriers, flexible carriers, traditional leadframes or laminates, and non-flat surfaces.

For example, a semiconductor wafer, may be processed through various stages, including photolithography, deposition, and etching, to create the circuit patterns. Once the circuits are formed, the wafer is cut, diced, or “singulated” into individual chips. The singulated chips are then moved to a substrate or carrier for further processing, such as packaging. Multiple different types of components can also be assembled on a common carrier or substrate for assemblies comprising different types of components within a single assembly, such as for heterogenous integration, which may include one or more sensor, discrete, optoelectronic, analog, microcontroller, memory, and logic. Packaging provides physical and electrical connections for the components to function within an assembly or device.

FIGS. 1A-1E, as known in the prior art, provide a number of schematic diagrams of a chip, die, or component 500 that is peeled from a first wafer adhesive 512 or a carrier tape 510, commonly referred to as dicing tape, to then move the components to a second carrier or substrate for subsequent packaging or use. The illustrated process comprises using one or more ejector needles 532 in removing the components 500. The illustrated process is the most common approach for removing components 500 from the wafer adhesive tape 512 or carrier tape 510 and is currently the industry standard for component removal from adhesives and tapes.

FIG. 1A illustrates an embodiment of an ejection system 530 comprising a single ejecting needle 532 while part (c) depicts multiple needles 532 as part of the ejection system 530. FIG. 1A further illustrates pick up head 520 which is further detailed in FIG. 1B, showing a vacuum line 210 to pick up the component 500. FIG. 1D illustrates a thin chip or component 500 bending during removal due to the flexibility of the thin or ultrathin component 500, until the component forms a crack 502, as is shown along the back surface of the component 500 as illustrated in the plan view of FIG. 1E. Cracks are problematic and ruin the components, making them unusable. Furthermore, when a backside of the components 500 is rough and not finely ground, polished, or etched, non-uniformities in the backside surface can allow the components to crack more easily during the needle ejection process.

### SUMMARY

An opportunity exists for an improved method of selective release of components from a wafer. Therefore, according to an aspect of the disclosure a method of transferring components for an electronic assembly may comprise providing an adhesive tape coupled to a support ring, the adhesive tape comprises a temperature activated release layer. A wafer may be coupled to the temperature activated release layer. The wafer may be singulated into a plurality of components, wherein a thickness of the wafer comprises a thickness less than 150 micrometers (μm). A first portion of the temperature activated release layer may be activated with a first dose of localized heat under a first plurality of components to cause the first portion of the temperature activated release layer to expand and reduce a bond between the first portion of the temperature activated release layer and the first plurality of components. The first plurality of components may be removed from the first portion of the temperature activated release layer using a pickup tool. A second portion of the temperature activated release layer may be activated with a second dose of localized heat under a second plurality of components to cause the temperature activated release layer to expand and reduce a bond between the temperature activated release layer and the second plurality of components after removing the first plurality of components. The second plurality of components may be removed from the second portion of the temperature activated release layer.

Further, according to various aspects the temperature activated release layer may be heat activated at a temperature in a range of 50° C. to 320° C. The components may comprise a width or a length less than 3 millimeters (mm). The plurality of components may comprises one or more of a semiconductor device, an active device, an analog device, a passive device, a memory die, a semiconductor chip, a chiplet, a power device, a transistor, an RF device, an RF switch, a high-electron-mobility transistor (HEMT) device, a bridge die, a dummy die, LEDs, solar cells, a laser device, optical amplifiers, photo diodes, and other micro-electronic and micro-optoelectronic devices, a MEMS, a sensor, a VCSEL, RFID components, a package, and a fan-out wafer level package (FOWLP). The temperature activated release layer may be formed as a layer as part of an adhesive tape. The adhesive tape may be coupled to a support ring. The temperature activated release layer may be formed as a thermal release adhesive comprising thermo expandable capsules or microspheres that expand when activated by heat. A component pickup may comprise a vacuum pickup, Van Der Waals force pickup, adhesive contact pickup, or electrostatic pickup. A component pickup and release may require an amount of time in a range of 0.001 to 5.0 seconds. Removing the first plurality of components and the second plurality of components may occur without an ejector pin or an ejector needle.

Further, according to various aspects the pickup tool may use an amount of force that is at least 50% less than what would be used for pickup with an ejector needle and without a temperature activated release layer. The pickup tool may operate with direct contact between the plurality of components and the pickup tool before the plurality of components are removed from the temperature activated release layer. The first plurality of components may be removed from the first portion of the temperature activated release layer using a pickup tool that is a gang pickup tool. The first dose of localized heat may be substantially equal to the second dose of localized heat. The second portion of the temperature activated release layer may be activated after removing the first plurality of components. The second plurality of components may be removed from the second portion of the temperature activated release layer after activating the second portion of the temperature activated release layer. The pickup tool may operate with direct contact between the plurality of components and the pickup tool before the plurality of components are removed from the temperature activated release layer. The first portion of the temperature activated release layer may be selectively activated by a dose of energy applied through a window of a mask, filter, screen, temperature-controlled device or shield with one or more windows. The first portion of the temperature activated release layer may be activated with a first dose of localized heat. The second portion of the temperature activated release layer may be activated with a second dose of localized heat that is substantially equal to the first dose of localized heat. A first portion of the temperature activated release layer may be activated by applying a first dose of localized heat to one or more of: a front surface of the wafer, a backside of the wafer, or both.

Further, according to various aspects applying a first dose of localized heat may comprise: applying bottom localized heat by a probe, applying top localized heat provided by a pickup tool, or both. The probe may be a bottom probe that provides heat and applies a small upward force to act as a low-force ejector for the plurality of components. The second portion of the temperature activated release layer may be activated after removing the first plurality of components. The second plurality of components may be removed from the second portion of the temperature activated release layer after activating the second portion of the temperature activated release layer. A die attach film (DAF) may be disposed between the wafer and the temperature activated release layer, wherein the wafer directly contacts a top surface of the DAF, and a bottom surface of the DAF contacts the temperature activated release layer. The plurality of components may be removed from the temperature activated release layer with at least a portion of the DAF being removed from the temperature activated release layer while remaining attached to the plurality of components. Thermally conductive particles may be provided within the adhesive tape to promote thermal conductivity. The first plurality of components may comprise large components with edge lengths in a range of 3 millimeters to 35 mm. The first plurality of components may comprise modules or packages, and the wafer comprises a reconstituted panel. The modules may further comprise multiple devices interconnected within the module or package, and edge lengths in a range of 3 millimeters to 100 mm or more.

According to another aspect of the disclosure, a method of transferring components for an electronic assembly may comprise providing an energy activated release layer, coupling a wafer to the energy activated release layer, singulating the wafer into a plurality of components, activating a first portion of the energy activated release layer with a first change in temperature, and removing a first portion of the plurality of components from the first portion of the energy activated release layer. A second portion of the energy activated release layer may be activated with a second change in temperature after removing the first portion of the plurality of components. A second portion of the plurality of components may be removed from the second portion of the energy activated release layer.

Further, according to various aspects at least one of the plurality of components may comprise a thickness less than 150 micrometers (μm). At least one of the plurality of components may comprise a width or a length less than 3 millimeters (mm). The first portion of the plurality of components may comprise a large component with edge lengths in a range of 3 millimeters to 35 mm. The first portion of the plurality of components may comprise modules or packages, and the wafer may comprise a reconstituted panel. The modules or packages may further comprise multiple devices interconnected within the modules, and edge lengths in a range of 3 millimeters to 100 mm or more. The plurality of components may comprise one or more of a package, a module, a semiconductor device, an active device, an analog device, a passive device, a memory die, a semiconductor chip, a chiplet, a power device, a transistor, an RF device, an RF switch, a HEMT device, a bridge die, a dummy die, LEDs, solar cells, a laser device, optical amplifiers, photo diodes, and other micro-electronic and micro-optoelectronic devices, a MEMS, a sensor, a VCSEL, and RFID components. The energy activated release layer may be formed as a layer within an adhesive tape. The adhesive tape may be coupled to a support ring. Activating the first portion of the energy activated release layer may be with a first change in temperature further comprising heating the first portion of the energy activated release layer to cause expansion of the first portion of the energy activated release layer. The energy activated release layer may be activated by cooling at a temperature in a range of −60° C. to 0° C. The energy activated release layer may be heat activated at a temperature in a range of 50° C. to 320° C. The energy activated release layer may be formed as a thermal release adhesive comprising thermo expandable capsules or microspheres that expand when activated. The thermo expandable capsules or microspheres may be expanded by exposing the thermo expandable capsules or microspheres to energy in the form of heat.

Further, according to various aspects the first portion of the plurality of components may be removed from the first portion of the energy activated release layer using a gang pickup tool. A component pickup may comprise a vacuum pickup, Van Der Waals pickup, adhesive contact, or electrostatic pickup. Component pickup and release may require an amount of time in a range of 0.001 to 5.0 seconds. The first portion of the plurality of components and the second portion of the plurality of components may be removed without using an ejector pin or an ejector needle. A component pickup tool may use an amount of force that is at least 50% less than what would be used for a pickup tool without an ejector needle and without a temperature activated release layer. The first portion of the energy activated release layer may be activated with a first dose of localized heat, and the second portion of the energy activated release layer may be activated with a second dose of localized heat that is substantially equal to the first dose of localized heat. The second portion of the energy activated release layer may be activated after removing the first portion of the plurality of components and the second portion of the plurality of components may be removed from the second portion of the energy activated release layer after activating the second portion of the energy activated release layer. A component pickup tool may operate with direct contact between the plurality of components and the component pickup tool before the plurality of components are removed from the energy activated release layer. The first portion of the energy activated release layer may be selectively activated by a dose of energy applied through a window of a mask, filter, screen, temperature-controlled device or shield with one or more windows.

Further, according to various aspects the first portion of the energy activated release layer may be activated with a first dose of localized heat, and. the second portion of the energy activated release layer may be activated with a second dose of localized heat that is substantially equal to the first dose of localized heat. The first portion of the energy activated release layer may be activated with a first change in temperature that further comprises cooling the first portion of the energy activated release layer to cause a reduction in adhesion of the first portion of the energy activated release layer. A reduction in adhesion may result from contraction of the first portion of the energy activated release layer. A first portion of the energy activated release layer may be activated by applying a first dose of localized heat to one or more of: a front surface of the wafer, a backside surface of the wafer, or both. A first dose of localized heat may be applied by one or more of: applying bottom localized heat by a probe, applying top localized heat provided by a pickup tool, or both. The probe may provide heat and apply a small upward force to act as a low-force ejector for the plurality of components. A second portion of the energy activated release layer may be activated after removing the first plurality of components, a second plurality of components may be removed from the second portion of the energy activated release layer after activating the second portion of the energy activated release layer. A DAF may be disposed between the wafer and the energy activated release layer, wherein a surface of the wafer directly contacts to a top surface of the DAF, and a bottom surface of the DAF contacts the energy activated release layer. The component may be removed from the energy activated release layer with at least a portion of the DAF being removed from the energy activated release layer while remaining attached to the component.

According to another aspect of the disclosure, a method of transferring components for an electronic assembly may comprise providing a wafer coupled to an energy activated release layer, singulating the wafer into a plurality of components, activating a first portion of the energy activated release layer, and removing a first component of the plurality of components from the first portion of the energy activated release layer.

Further, according to various aspects the plurality of components may comprise a thickness less than 150 micrometers (μm). The plurality of components comprises a width or a length less than 3 millimeters (mm). The first plurality of components may comprise large components with edge lengths in a range of 3 millimeters to 35 mm. The first plurality of components may comprise modules or packages, and the wafer may comprise a reconstituted panel. The modules or packages may further comprise multiple devices interconnected within the module, and edge lengths may be in a range of 3 millimeters to 100 mm or more. The plurality of components may comprise one or more of a module, a package, a semiconductor device, an active device, an analog device, a passive device, a memory die, a semiconductor chip, a chiplet, a power device, a transistor, an RF device, an RF switch, a HEMT device, a bridge die, a dummy die, LEDs, solar cells, a laser device, optical amplifiers, photo diodes, and other micro-electronic and micro-optoelectronic devices, a MEMS, a sensor, a VCSEL, and RFID components. The energy activated release layer may be formed as a layer within an adhesive tape. The adhesive tape may be coupled to a support ring. Activating the first portion of the energy activated release layer may occur with a change in temperature and not with ultraviolet (UV) light.

Further, according to various aspects the first portion of the energy activated release layer may be activated with a first change in temperature of the first portion of the energy activated release layer to cause a reduction in adhesion and an expansion of the first portion of the energy activated release layer. The reduction in adhesion may comprise a change of surface topography and an expansion of the energy activated release layer due to heating the first portion of the energy activated release layer. The reduction in adhesion may comprise a change of surface topography and a contraction of the energy activated release layer due to cooling of the first portion of the energy activated release layer. The temperature activated release layer may be activated by cooling at a temperature in a range of −60°° C. to 0° C. The temperature activated release layer may be heat activated at a temperature in a range of 50° C. to 320° C. The energy activated release layer may be formed as a thermal release adhesive comprising thermo expandable capsules or microspheres that expand when activated. The thermal release adhesive may be activated by exposing the thermal release adhesive to energy in the form of heat. The thermal release adhesive may further comprise thermally conductive particles or fillers to increase the thermal conductivity of the thermal release adhesive. The thermal release adhesive may be formed as a thermal release tape comprising a tape base material, wherein the tape base material comprises thermally conductive particles or fillers to increase the thermal conductivity of the thermal release tape that increase heat transfer through the tape.

Further, according to various aspects the plurality of components may be removed from the first portion of the energy activated release layer using a gang pickup. The plurality of components may be removed from the first portion of the energy activated release layer using a vacuum pickup. A component pickup may comprise a vacuum pickup, Van Der Waals force pickup, adhesive contact pickup, or electrostatic pickup. A component pickup and release may require an amount of time in a range of 0.001 to 5.0 seconds. The plurality of components may be removed without using an ejector pin or an ejector needle. A component pickup may use an amount of force that is at least 50% less than what would be used for pickup without an ejector needle and without a temperature activated release layer. A component pickup tool may operate with direct contact between the plurality of components and the component pickup tool before the plurality of components are removed from the energy activated release layer. The first portion of the energy activated release layer may be selectively activated by a dose of energy applied through a window of a mask, filter, screen, temperature-controlled device or shield with one or more windows.

Further, according to various aspects the first portion of the energy activated release layer may be activated with a first dose of localized heat, and a second portion of the energy activated release layer may be activated with a second dose of localized heat that is substantially equal to the first dose of localized heat. The first portion of the energy activated release layer may be activated with a first change in temperature that comprises cooling the first portion of the energy activated release layer to cause a reduction in adhesion of the first portion of the energy activated release layer. A reduction in adhesion may result from contraction of the first portion of the energy activated release layer. A first portion of the energy activated release layer may be activated by applying a first dose of localized heat to one or more of: a first top surface of the wafer, a second bottoms surface of the wafer, or both. A first dose of localized heat may be applied by: applying bottom localized heat by a probe, applying top localized heat provided by a pickup tool, or both. The probe may provide heat and apply a small upward force to act as a low-force ejector for the plurality of components. A second portion of the energy activated release layer may be activated after removing the first plurality of components, and a second plurality of components may be removed from the second portion of the energy activated release layer after activating the second portion of the energy activated release layer. A DAF may be disposed between the wafer and the energy activated release layer, wherein a surface of the wafer directly contacts to a top surface of the DAF, and a bottom surface of the DAF contacts the energy activated release layer. The component may be removed from the energy activated release layer with at least a portion of the DAF being removed from the energy activated release layer while remaining attached to the component. The component may be removed from the energy activated release layer by removing a known good component, and further comprising leaving any of the plurality of components that are not known good components.

The foregoing and other aspects, features, and advantages will be apparent from the description and drawings, and from the claims. Unless specifically noted, it is intended that the words and phrases in the specification and the claims be given their plain, ordinary, and accustomed meaning to those of ordinary skill in the applicable arts. The inventors are fully aware that they can be their own lexicographer if desired. The inventors expressly elect, as their own lexicographers, to use only the plain and ordinary meaning of terms in the specification and claims unless they clearly state otherwise and then further, expressly set forth the “special” definition of that term and explain how it differs from the plain and ordinary meaning. Absent such clear statements of intent to apply a “special” definition, it is the inventors' intent and desire that the simple, plain and ordinary meaning to the terms be applied to the interpretation of the specification and claims.

The inventors are also aware of the normal precepts of English grammar. Thus, if a noun, term, or phrase is intended to be further characterized, specified, or narrowed in some way, then such noun, term, or phrase will expressly include additional adjectives, descriptive terms, or other modifiers in accordance with the normal precepts of English grammar. Absent the use of such adjectives, descriptive terms, or modifiers, it is the intent that such nouns, terms, or phrases be given their plain, and ordinary English meaning to those skilled in the applicable arts as set forth above.

Further, the inventors are fully informed of the standards and application of the special provisions of 35 U.S.C. § 112 (f). Thus, the use of the words “function,” “means” or “step” in the Detailed Description or Description of the Drawings or claims is not intended to somehow indicate a desire to invoke the special provisions of 35 U.S.C. § 112 (f), to define the invention. To the contrary, if the provisions of 35 U.S.C. § 112 (f) are sought to be invoked to define the inventions, the claims will specifically and expressly state the exact phrases “means for” or “step for”, and will also recite the word “function” (i.e., will state “means for performing the function of [insert function]”), without also reciting in such phrases any structure, material or act in support of the function. Thus, even when the claims recite a “means for performing the function of . . . ” or “step for performing the function of . . . ,” if the claims also recite any structure, material or acts in support of that means or step, or that perform the recited function, then it is the clear intention of the inventors not to invoke the provisions of 35 U.S.C. § 112 (f). Moreover, even if the provisions of 35 U.S.C. § 112 (f) are invoked to define the claimed aspects, it is intended that these aspects not be limited only to the specific structure, material or acts that are described in the preferred embodiments, but in addition, include any and all structures, materials or acts that perform the claimed function as described in alternative embodiments or forms of the disclosure, or that are well known present or later-developed, equivalent structures, material or acts for performing the claimed function.

### BRIEF DESCRIPTION OF THE DRAWINGS

Implementations will hereinafter be described in conjunction with the appended and/or included drawings, where like designations denote like elements, and:

FIGS. 1A-1E are representations of a typical prior art system for removing components from an adhesive or carrier tape;

FIGS. 2A-2B are illustrations of components comprising electrical interconnects being singulated from a substrate or native wafer;

FIGS. 2C-2M depict various stages of a wafer, module or panel being singulated into components which are removed from an adhesive tape;

FIGS. 3A-3D are representations of various embodiments of thermally activated release layers applied to a component;

FIGS. 4A-4B show embodiments of multi-layered expanding adhesive tapes;

FIGS. 5A-5C depict embodiments of expanding adhesive tapes applied to a component;

FIGS. 6A-6C show embodiments of multi-layer contracting adhesive tapes;

FIGS. 7A-7B show an adhesive tape including a die attach film and a thermally activated film as applied to a component;

FIG. 7C illustrates removal of a component from a thermally activated film, and

FIG. 8 illustrates an exemplary electronic assembly.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of implementations.

### DETAILED DESCRIPTION

Detailed aspects and applications of the disclosure are described below in the following drawings and detailed description of the technology.

In the following description, and for the purposes of explanation, numerous specific details are set forth in order to provide a thorough understanding of the various aspects of the disclosure. It will be understood, however, by those skilled in the relevant arts, that embodiments of the technology disclosed herein may be practiced without these specific details. It should be noted that there are many different and alternative configurations, devices and technologies to which the disclosed technologies may be applied. The full scope of the technology disclosed herein is not limited to the examples that are described below.

The singular forms “a,” “an,” and “the” include plural referents unless the context clearly dictates otherwise. Thus, for example, reference to “a step” includes reference to one or more of such steps.

The present disclosure includes one or more aspects or embodiments in the following description with reference to the figures, in which like numerals represent the same or similar elements. Those skilled in the art will appreciate that the description is intended to cover alternatives, modifications, and equivalents as may be included within the spirit and scope of the disclosure as defined by the appended claims and their equivalents as supported by the following disclosure and drawings. In the description, numerous specific details are set forth, such as specific configurations, compositions, and processes, etc., in order to provide a thorough understanding of the disclosure. In other instances, well-known processes and manufacturing techniques have not been described in particular detail in order to not unnecessarily obscure the disclosure. Furthermore, the various embodiments shown in the FIGs. are illustrative representations and are not necessarily drawn to scale.

This disclosure, its aspects, and implementations, are not limited to the specific package types, material types, or other system component examples, or methods disclosed herein. Many additional components, manufacturing and assembly procedures known in the art consistent with semiconductor wafer fabrication, manufacture and packaging are contemplated for use with particular implementations from this disclosure. Accordingly, for example, although particular implementations are disclosed, such implementations and implementing components may comprise any components, models, types, materials, versions, quantities, or the like as is known in the art for such systems and implementing components, consistent with the intended operation.

The word “exemplary,” “example,” or various forms thereof are used herein to mean serving as an example, instance, or illustration. Any aspect or design described herein as “exemplary” or as an “example” is not necessarily to be construed as preferred or advantageous over other aspects or designs. Furthermore, examples are provided solely for purposes of clarity and understanding and are not meant to limit or restrict the disclosed subject matter or relevant portions of this disclosure in any manner. It is to be appreciated that a myriad of additional or alternate examples of varying scope could have been presented, but have been omitted for purposes of brevity.

When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

Throughout the description and claims of this specification, the words “comprise” and “contain” and variations of the words, for example “comprising” and “comprises”, mean “including but not limited to”, and are not intended to (and do not) exclude other components.

As required, detailed embodiments of the present disclosure are included herein. It is to be understood that the disclosed embodiments are merely exemplary of the invention that may be embodied in various forms. Therefore, specific structural and functional details disclosed herein are not to be interpreted as limits, but merely as a basis for teaching one skilled in the art to employ the present invention. The specific examples below will enable the disclosure to be better understood. However, they are given merely by way of guidance and do not imply any limitation.

The present disclosure may be understood more readily by reference to the following detailed description taken in connection with the accompanying figures and examples, which form a part of this disclosure. It is to be understood that this disclosure is not limited to the specific materials, devices, methods, applications, conditions, or parameters described and/or shown herein, and that the terminology used herein is for the purpose of describing particular embodiments by way of example only and is not intended to be limiting of the claimed inventions. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

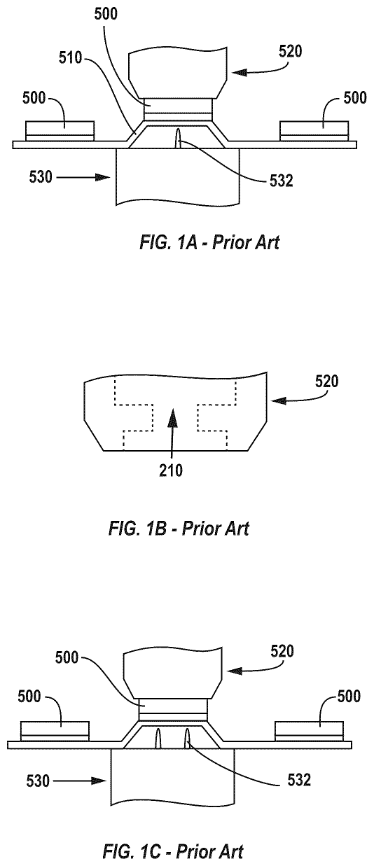

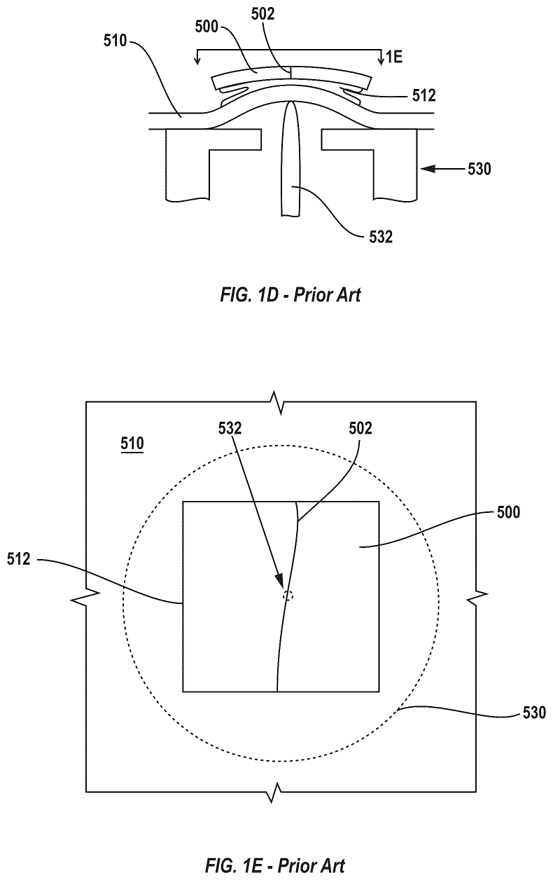

Applicant's disclosure relates to devices, methods, and processes for manufacturing assemblies, electronic devices, or packages. The formation of the assemblies comprises moving semiconductor chips, modules or packages, and other components from a first (donor) substrate, which may comprise any of a semiconductor wafer, a diced wafer, a reconstituted panel, and a carrier, to a second (receiver) substrate or carrier for further processing. The components can include one or more of a semiconductor device, an active device, an analog device, a passive device, a memory die, a semiconductor chip, a chiplet, a power device, a transistor, an RF device, an RF switch, a high-electron-mobility transistor (HEMT) device, a bridge die, a dummy die, LEDs, solar cells, a laser device, optical amplifiers, photo diodes, and other micro-electronic and micro-optoelectronic devices. a MEMS, a sensor, a VCSEL, RFID components, a package, a fan-out wafer level package (FOWLP), or any other suitable component. As used herein, LEDs comprise mini-LEDs, which comprise edges with lengths in a range of about 100-200 μm, and micro-LEDs which comprise edges with lengths in a range of less than about 100 μm. According to some embodiments, the components may be similar to, or the same as, the components as earlier described with reference to the prior art FIGS. 1A-1E. In some instances, the components may be one or more of the same type of component. In further instances, the components may comprise one or more components which are of different types. According to further embodiments, the components may be combined together in any combination to form a module for subsequent transfer from the first substrate. The methods for release of components as disclosed herein is useful for all of the aforementioned components and other suitable components, regardless of component type.

Once on the second substrate, the components can undergo further processing, such as packaging. The components may be moved from the first substrate to the second substrate individually; or using a gang transfer, or Micro Transfer Printing (μTP), or other suitable transfer process for mass production, which involves the simultaneous pickup, manipulation, and placement of multiple components onto various second substrates. This process can be repeated multiple times on the same substrate to create complex, multi-component or multi-layer structures, and includes machine vision and control algorithms to ensure high-precision placement and alignment of components.

Transfer of components from the first substrate to a second substrate may be accomplished by using an energy activated release layer, such as a temperature activated release layer, also referred to herein as a thermal release layer and a thermal release adhesive. While the temperature activated release layer may relate to the use of thermal energy and temperature, a person of ordinary skill in the art (POSA) would understand that other energy activated materials, which are activated by forms of energy in addition to temperature, such as visible light, infra-red (IR), ultra violet (UV) light, or other suitable sources of energy, may be included as part of the temperature activated release layer. The method may comprise: (i) providing an adhesive tape 130 coupled to a support ring 120, wherein the adhesive tape 130 comprises a temperature activated release layer 140; (ii) coupling a wafer to the temperature activated release layer 140; (iii) singulating the wafer into a plurality of components, wherein a thickness of the wafer comprises a thickness less than 150 micrometers (μm); (iv) activating a first portion of the temperature activated release layer 140 with a first dose of localized heat under a first plurality of components to cause the first portion of the temperature activated release layer to expand and reduce a bond between the first portion of the temperature activated release layer and the first plurality of components; (v) removing the first plurality of components from the first portion of the temperature activated release layer using a pickup tool; (vi) activating a second portion of the temperature activated release layer with a second dose of localized heat under a second plurality of components to cause the temperature activated release layer to expand and reduce a bond between the temperature activated release layer and the second plurality of components after removing the first plurality of components, and (vii) removing the second plurality of components from the second portion of the temperature activated release layer.

In some instances, the temperature activated release layer 140 is activated by heating, such as by heating to a temperature in a range of about 50° C. to 320° C., or about 150° C. to 180° C. causing the temperature activated release layer 140 to expand and reduce adhesion. In other instances, the temperature activated release layer 140 is activated by cooling, such as by cooling to −60°° C. to 0°° C. According to some embodiments, the temperature activated release layer 140 may comprise an energy activated release layer 140, which may be activated by visible light, infra-red (IR), ultra violet (UV) light, or other suitable source of energy. In some instances, the loss of adhesion may be caused by, or result from, a chemical change in the adhesive due to a change in energy. The force needed to remove the components 14 from the adhesive tape 130 or temperature activated or energy activated release layer 140 may be reduced by 50-99% after the temperature or energy activation. In some instances, IR may be used to pass through a component 14 comprising Si, SiGe or GaAs (which are highly transmissive to IR) and activate the energy activated release layer 140 after having passed through the component 14 comprising Si, SiGe or GaAs.

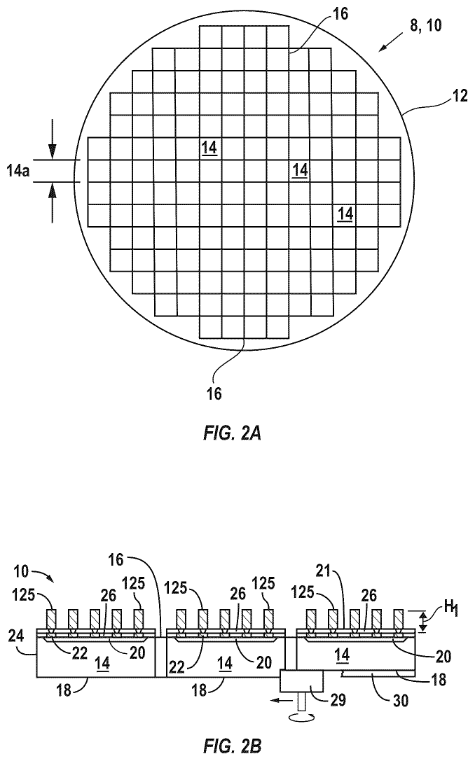

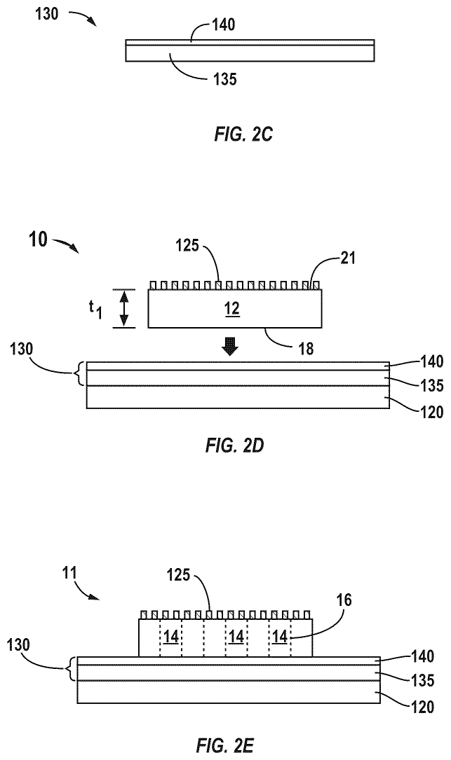

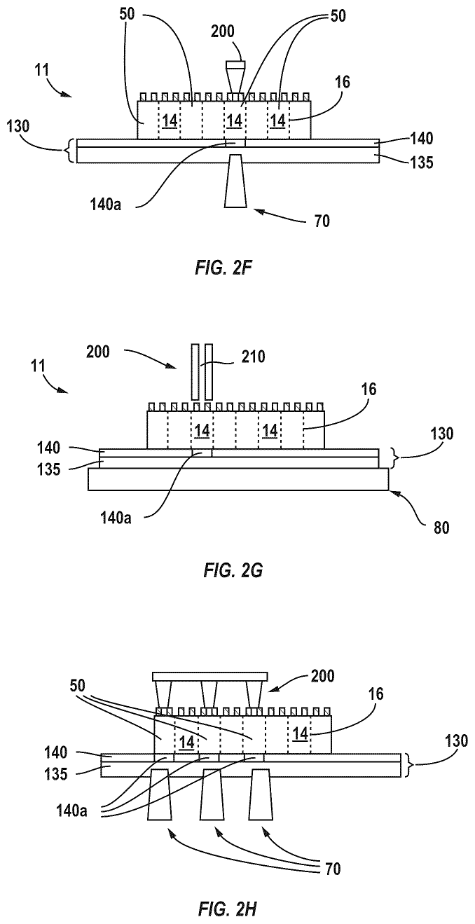

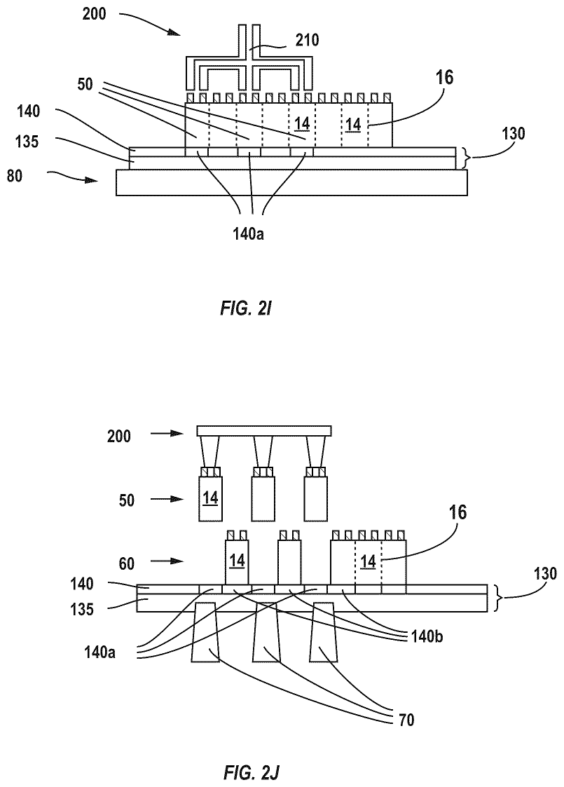

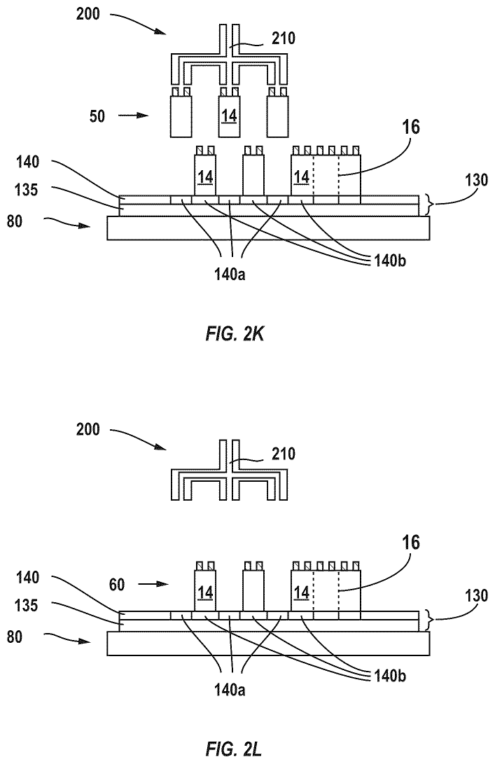

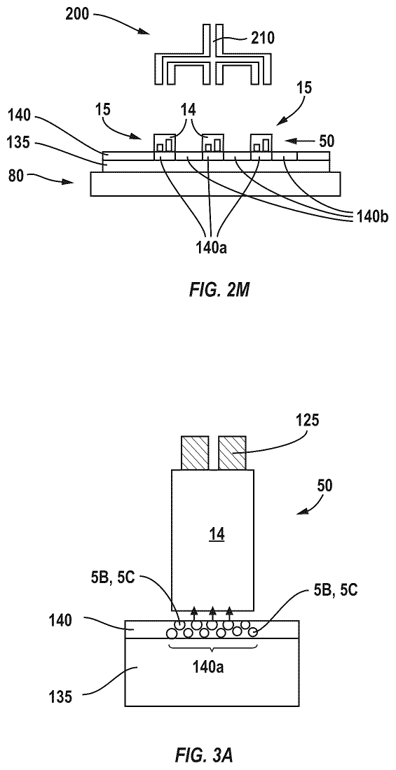

FIG. 2A shows a plan or top view of a substrate 8, which may comprise a first substrate 10, comprising any of a wafer, semiconductor wafer or native wafer with a base substrate material 12, such as, without limitation, silicon (Si), silicon dioxide (SiO₂), germanium (Ge), gallium arsenide (GaAs), indium phosphide (InP), gallium nitride (GaN), silicon nitride (Si₃N₄), or silicon carbide (SiC), for the base substrate material 12. In some instances, material selection for the base substrate material 12 may be optimized or selected for one or more parameters of performance. For example, to reduce power consumption in electric vehicle applications, components 14 comprising power devices and RF power amplifiers could be formed of GaN, SiC, or GaAs, instead of Si, to reduce power consumption (e.g., on the order of 3×) and to produce electric vehicles (EVs) that save approximately 80% energy and double EV mileage range with respect to electric vehicles operating using Si based power devices.

In some instances, the first substrate 10 may also comprise a reconstituted panel, module, or other structure comprising multiple components 14 and components 14 of different types. Components 14, and a first or second plurality of components, 50 or 60 respectively as described with respect to FIG. 2J following, can be formed on a first substrate 10 comprising a wafer and be separated by a non-active, inter-component wafer area or saw street 16 as described above. The saw street 16 can provide cutting areas to singulate the first substrate 10 comprising a semiconductor wafer 10 into the individual components or semiconductor component 14. Components 14 may have an edge length 14a, representing a width or length of components 14. In various instances, components 14 may comprise one or more of: a semiconductor device, an active device, an analog device, a passive device, a memory die, a semiconductor chip, a chiplet, a power device, a transistor, an RF device, an RF switch, a high-electron-mobility transistor (HEMT) device, a bridge die, a dummy die, LEDs, solar cells, a laser device, optical amplifiers, photo diodes, and other micro-electronic and micro-optoelectronic devices, a MEMS, a sensor, a VCSEL, and RFID components that may become embedded devices and can be formed on a substrate 8 formed of glass, ceramic, or other suitable material for providing structural support for subsequent processing.

Each component 14 may comprise one or more active devices, passive devices, or both active devices and passive devices. In some instances, component 14 may be formed without active and passive devices, and be used for transmission or routing, such as by comprising TSVs for vertical interconnect. For example, component 14 may be formed as a bridge chip with only electrical routing and with copper studs of the semiconductor chip electrically connected or coupled with wiring, routing, or RDL of the bridge chip. Component 14 may also be only a dummy substrate with no electrical function, but rather act as structural element and may or may not include copper studs. Components 14 may also be any of the other elements disclosed herein or other similar or suitable component.

The component 14 may comprise semiconductor chips and semiconductor die or components 14 that comprise a backside or back surface 18, and a front surface 21 opposite the backside 18, the front surface 21 comprising at least one active layer 20. In some instances, both the front surface 21 and backside 18 of the component 14 will be active or contain one or more analog circuits, digital circuits, optical devices like a light emitting diode (LED), a vertical cavity surface emitting laser (VCSEL), one or more power transistors implemented as active devices, conductive layers, or dielectric layers formed within or on the component 14 and electrically interconnected according to the electrical design and function of the component 14. In some instances, passive devices may also be integrated as part of component 14. The component 14 may comprise circuits that may include one or more transistors, diodes, and other circuit elements formed within the active layer to implement analog circuits or digital circuits, such as DSP, ASIC, memory, or other signal processing circuits. Circuits (analog or digital) may comprise RF circuits, LED, LCOS, CIS, transistor, diode, optoelectronic, MEMS and the like. Component 14 may also contain IPDs such as inductors, capacitors, and resistors, for RF signal processing, digital power line control or other functions. Component 14 may be formed on a first substrate 10 comprising a native wafer. In some instances, a wafer level process may be used to produce many packages or modules simultaneously on a carrier. In other instances, a package or module 15 (as depicted in FIG. 2M following) may be formed as part of a first substrate 10 comprising a reconstituted wafer, and may comprise multiple components 14 or chips molded together.

FIG. 2B illustrates a cross-sectional side view (perpendicular to the view of FIG. 2A) which illustrates a portion of a first substrate comprising semiconductor wafer 10 disposed over a die attach film 30. Each component 14 is shown comprising a backside or back surface 18, a front surface 21, and an active layer 20 opposite the backside. However, in some instances component 14 may not comprise an active layer 20.

An electrically conductive layer or contact pads 22 may be formed over active layer 20 using PVD, CVD, electrolytic plating, electroless plating process, or other suitable metal deposition process. Conductive layer 22 can be one or more layers of aluminum (Al), copper (Cu), tin (Sn), nickel (Ni), gold (Au), palladium (Pd), silver (Ag), cobalt (Co), platinum (Pt), or other suitable electrically conductive material. Portions of conductive layer 22 may operate as contact pads or bond pads electrically coupled or connected to the circuits on active layer 20. Portions of conductive layer 22 can be formed as contact pads disposed side-by-side a first distance from an edge 24 of component 14, as shown in FIG. 2B. Alternatively, portions of conductive layer 22 can be formed as contact pads 22 that are offset in multiple rows such that a first row of contact pads 22 is disposed a first distance from the edge 24 of the component 14, and a second row of contact pads alternating with the first row is disposed a second distance from the edge 24 of the component 14. In other instances, the component 14 can comprise digital chips, analog chips, or RF chips (or other chips) with more than two rows of bond pads, and may further comprise bond pads 22 over the whole surface of the chip that do not follow a full grid pattern. Other components 14 may have bond pads 22 in an array over the entire front surface 21 of the chip or component 14.

FIG. 2B also illustrates the first substrate or semiconductor substrate 10 and components 14 can undergo an optional grinding operation with grinder 29 to reduce a thickness of the semiconductor substrate 10 and component 14. The thinning or grinding operation may be part of a singulation or dicing operation (hereinafter collectively “singulation” or variations thereof) or separate from it. In some instances, a backside plasma or a wet etch may be used to remove backside material from the backside 18 of components 14, such as to remove grinding or polishing scratches, as well as to reduce a thickness of the components 14.

Singulation may occur before, after, or as part of grinding; and any suitable approach for singulating the first substrate 10 comprising the wafer consistent with the temperature activated release layer 140 may be used. Acceptable singulation techniques include: Blade Dicing, Laser Dicing (Stealth or Ablative), Grind After Laser (GAL), Plasma Dicing, Dice Before Grind (DBG), Water Jet Dicing, Scribe and Break, and combined methods like laser “grooving” followed by plasma or saw dicing, or other suitable process that is compatible with the temperature activated release layer 140 as described herein. Additional detail of the various singulation techniques is included below.

Blade Dicing uses a saw blade of diamond or other suitable material is used to mechanically cut the wafer 10 into individual die or components 14, and is generally cost-effective and versatile, although it may cause damage to the wafer 10 and produce debris.

Laser Dicing employs a laser to separate the die or components 14. Stealth Dicing, a variant of laser dicing, involves creating crack initiators internally within the wafer 10. The wafer 10, at a greater thickness (including at a full thickness of 780 μm for a 300 mm wafer), is partially processed from the active side 20 or front surface 21 while mounted on a release tape to remove metal from the scribe lines, then the wafer 10 is processed with a laser beam focused an appropriate depth into the base substrate material 12 comprising silicon, which disrupts the silicon lattice to create an internal stress riser. The wafer singulation occurs when the release tape is stretched, and stretching occurs after backgrinding to reduce wafer thickness and to expose the previously formed singulation trenches.

A similar methodology to stealth dicing is Grind After Laser (GAL), which uses laser ablation singulation at full wafer thickness, with the wafer 10 mounted active side 20 or front surface 21 up. After the laser process, the wafer 10 is flipped active side 20 or front surface 21 down onto the release tape, then backgrinding is performed to both reduce thickness and expose the previously formed singulation trenches, thereby singulating the wafer 10.

Plasma Dicing uses a plasma etch process to dice the wafer 10. The wafer 10 may or may not be pre-processed to remove metal structures in the saw street 16 and may also include laser grooving which is known to create an edge seal for sensitive low k dielectric layers. This method includes coating the wafer 10 with a protective coating and creating a photolithography defined pattern which exposes the saw streets 16. The wafer 10 is then submitted to a special vacuum-based plasma process which cuts through the wafer 10 that has been pre-thinned to a typical thickness of 100 μm or less. After plasma dicing, the wafer 10 is transferred face or front surface 21 down onto the release tape, then backgrinding is performed to both reduce thickness and expose the previously formed singulation trenches, thereby singulating the wafer 10.

Dice Before Grind (DBG) is a method that involves partial depth dicing the wafer 10 before it is thinned sufficiently by grinding to singulate the die or components 14. The wafer 10 is is processed through a partial-depth singulation step, and then it is thinned by grinding, which also completes the singulation.

Less common methods include Water Jet Dicing, which uses a high-pressure jet of water to cut the wafer 10, and Scribe and Break, which involves scribing a line on the wafer 10 and then applying force to break the wafer 10 along the scribed line.

Finally, sometimes two dicing or singulation processes are combined. For example, laser “grooving” can be used to remove test structures that include metal in the saw street 16 before doing plasma dicing, as plasma is ineffective for cutting through the metal. Another example is laser grooving followed by saw dicing. Combined methods allow for more flexibility and precision in the singulation process, but they can also be more complex and may require special equipment and procedures. Various singulation methods may accommodate the orientation of the wafer 10 being face or front surface 21 up, face or front surface 21 down, or both face or front surface 21 up and face or front surface 21-down during portions of the process. Any of the aforementioned singulation processes as disclosed for a first substrate 10 comprising a wafer may be useful for singulation of a first substrate 10 comprising a panel or reconstituted panel, or a module 15.

The individual components 14, during processing and in their final singulated state) may comprise a thickness in a range of 2-780 micrometers (μm), and may result in thin components 14 comprising a thickness less than 150 μm or less than 300 μm. According to some embodiments, the components 14 may comprise a thickness of from 2-150 μm, and in yet further embodiments, the components 14 may comprise a thickness of from 2-50 μm. Thin components 14 may be more susceptible or particularly susceptible to breaking under conventional handling, which typically utilizes conventional ejector pins or ejector needles as depicted in FIGS. 1A-1E. Use of conventional ejector pins or ejector needles 532 causes defects and damage to backsides 18 of the components 14, particularly at the point of contact of the backside 18 with the ejector pins or needles, causing cracks 502 as depicted in FIG. 1E, and reducing the fracture strength of the components 14. Such contact of backside 18 with the ejector pins or needles 532 may not pose issue with full thickness or near full thickness components, but as component thicknesses decrease, fracture strength decreases correspondingly. As such, thin components 14 may particularly benefit from the method and process described herein of transferring components 14 without the need for, or use of, conventional ejector pins or ejector needles 532, but rather with the temperature activated release layer 140 as disclosed herein.

FIG. 2B further shows one or more optional insulating, passivating, or dielectric layers 26 that may be applied over active layer 20 and over conductive layer 22. Insulating layer 26 can include one or more layers that are applied using PVD, CVD, PECVD, screen printing, spin coating, spray coating, sintering, thermal oxidation, or other suitable process. Insulating layer 26 can contain, without limitation, one or more layers of silicon dioxide (SiO₂), silicon nitride (Si₃N₄), silicon oxynitride (SiON), low k dielectric materials, tantalum pentoxide (Ta₂O₅), aluminum oxide (Al₂O₃), polymer, polyimide, benzocyclobutene (BCB), polybenzoxazoles (PBO), or other material having suitable insulating and structural properties. Alternatively, component 14 is packaged without the use of insulating layer 26. When insulating layer 26 is present and formed over conductive layer 22, openings are formed completely through insulating layer 26 to expose at least a portion of conductive layer 22 for subsequent mechanical and electrical interconnection. Alternatively, when insulating layer 26 is omitted, conductive layer 22 is exposed for subsequent electrical interconnection without the formation of openings.

FIG. 2B shows conductive studs 125 can be formed as bumps, thick pads, columns, pillars, posts, or conductive stumps and are disposed over, and coupled or connected to, contact pads 22. In other instances, the components 14 will be formed without conductive studs 125. The conductive studs 125 can be formed directly on contact pads 22 using patterning and metal deposition processes such as printing, PVD, CVD, sputtering, electrolytic plating, electroless plating, evaporation, or other suitable metal deposition process. Alternately, conductive studs 125 may be formed in a position not vertically over the pads 22 and connected by RDL. Conductive studs 125 can be one or more layers of Al, Ti, TiW, Ta, Cu, Sn, Ni, Au, Ag, palladium (Pd), or other suitable electrically conductive material and can include one or more under-bump metallization (UBM) layers. In an embodiment, a photoresist layer can be deposited over component 14 and contact pads 22. A portion of the photoresist layer can be exposed and removed by a developing or other suitable process. Conductive studs 125 can then be formed as studs, bumps, pillars or other structures as previously described in the removed portion of the photoresist and over contact pads 22 using a plating process. In some embodiments, copper may be used in a plating process. The photoresist layer and other appropriate layers, such as a seed layer, can be removed leaving conductive studs 125 that provide for subsequent mechanical and electrical interconnection and a standoff with respect to active layer 20 and insulating layer 26 if present. In some instances, the conductive studs 125 include a height in a range of 1-100 micrometers (μm), 2-50 μm, or about 25 μm.

In some instances, the conductive studs 125 will be formed as conductive studs, which are connected with or directly contact the component 14 or the contact pads 22 of the component 14. Similarly, conductive stumps may have a same or similar structure to the conductive studs, with the conductive stumps differing from the conductive studs in that the conductive stumps are vertically offset from the conductive studs, such as being formed as later layer such that the conductive stumps are coupled with, but do not directly contact, or are not directly connected with, the component 14. Conductive stumps may be used for coupling with the component 14, such as part of build-up interconnect structures for the transfer or routing of one or more of electrical signals, power, ground, and for thermal transfer. Stated another way, the conductive studs may differ from conductive stumps in that the conductive studs are formed on the native wafer before singulation of the native wafer and the conductive stumps, if present, would be formed after singulation of the native wafer and added as part of subsequent processing, such as during formation of packaging structure.

Conductive studs and conductive stumps are conductive interconnect structures that may have generally vertical sides and be wider than tall. A conductive stud or stump may differ from a pillar or post, each of which may have a height greater than its width. A conductive stud or stump may comprise a cylindrical shape and may further be formed with a cross-sectional area that is circular, oval, octagonal, rectangular with radiused corners, or as any polygonal or other shape and size. A conductive stud or stump may be used for electrical interconnect, signal transmission, power, ground, or as a dummy thermal element that is not electrically coupled to an active electrical circuit but is instead thermally coupled to a heat source of an active device to dissipate the heat to another structure, such as to a thermal pad on a surface of the component 14 or on a package or module housing the component 14. The generally vertical sides of a conductive stud or stump are different from the sides shape that exists for a solder ball or a compressed or outwardly deformed solder ball that has generally rounded or ovoid sides. The generally vertical nature of a conductive stud or stump comes from being formed in a structure that has been previously developed or etched, such as within openings in a photoresist layer, which will also be generally vertical. Sides of the conductive stud or stump may comprise imperfections or irregularities in shape that result from the developing or etching process, the photoresist material, or other materials and processes used. For example, developing or etching does not generally perfectly or uniformly remove the photoresist within the openings, and therefore forms imperfect, generally vertical openings for deposition of the conductive stud or stump. The term “generally vertical” as used herein includes perfectly vertical and imperfectly vertical sides or sides that are about or substantially vertical or at an angle typically greater than 45 degrees. A conductive stud or stump is not a wire bond and is not solder.

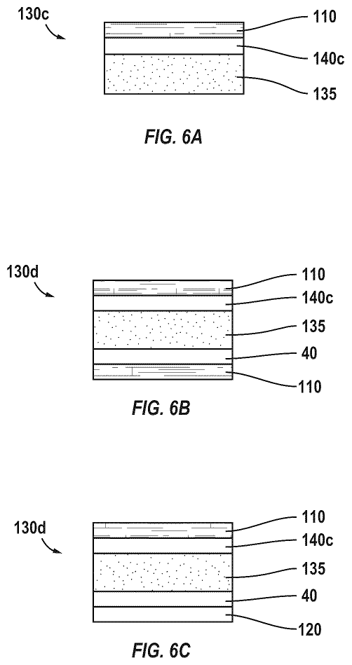

FIG. 2C illustrates an embodiment of an adhesive tape 130 comprising a temperature activated release layer 140. The adhesive tape 130 may be made by starting with a base film 135 and then adding at least one thermal release layer 140 to the base film 135. According to some embodiments, the temperature activated release layer 140 may be formed as a layer or thermal adhesive layer as part of the adhesive tape 130. An optional liner 110 (as shown for example in FIGS. 4A-4B) may then be added (depending on how the tape is supplied) to protect or cover one or more of the base layer 135 or the thermal release layer 140, until exposure of at least one of the covered layers is desired. As shown in FIGS. 2D and 6C, a temporary carrier or support ring 120 may be used, and the adhesive tape 130 may be adhered or coupled thereto. Support ring 120 may comprise a carrier, a saw ring or dicing ring, or a film frame. The adhesive tape 130 in FIG. 2C comprises an adhesive layer comprising a thermal release layer 140 that is labeled (as a non-limiting example) as a “thermal foaming adhesive.” The adhesive tape 130 may comprise a single layer or coating of thermal release layer 140, or the adhesive tape 130 may be a multi-layer film comprising multiple layers or coatings or thermal release layers 140. The thermal release layer 140 may also be disposed on a glass carrier (or other suitable carrier)—such as a contact film that may be spin coated, spray coated, slit coated or otherwise suitably disposed thereon, whether directly or indirectly. The thermal release layer 140 may be activated by hot temperatures or cold temperatures.

When heated or cooled, the thermal release layer 140 may undergo structural changes, such as phase changes, or physical changes such as bubbling micro-spheres, or expansion and contraction due to thermal expansion and contraction (based on a material's coefficient of thermal expansion (CTE)) to reduce its adhesion to the components 14, allowing the components 14 to be picked up or more easily removed from the thermal release layer 140. In some instances, the adhesive tape 130 may comprise multiple regions or layers that have the same or different activation temperatures, allowing different groups of components 14 to be released at different times. The temperature activated release layers 140 may be applied one on top of the other, or adjacent to each other on the adhesive tape 130, or over the first substrate 10 (not shown in FIG. 2C).

The temperature activated release layer 140 may be activated by heating to an elevated temperature, such as in a range of 120°° C. to 320°° C. When heated, the release layer 140 expands, reducing its adhesion to the components 14 so they can be picked up. Alternatively, the release layer 140 may be activated by cooling to a reduced temperature, such as in a range of −60° C. to 0° C. When cooled, the temperature activated release layer 140 contracts or stiffens, reducing its adhesion to the components 14.

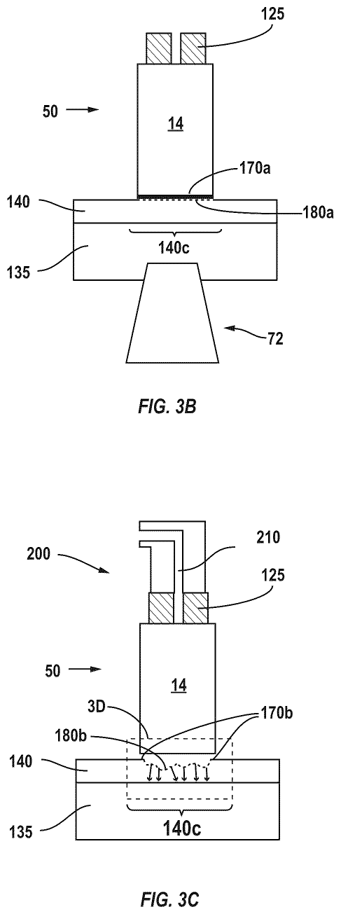

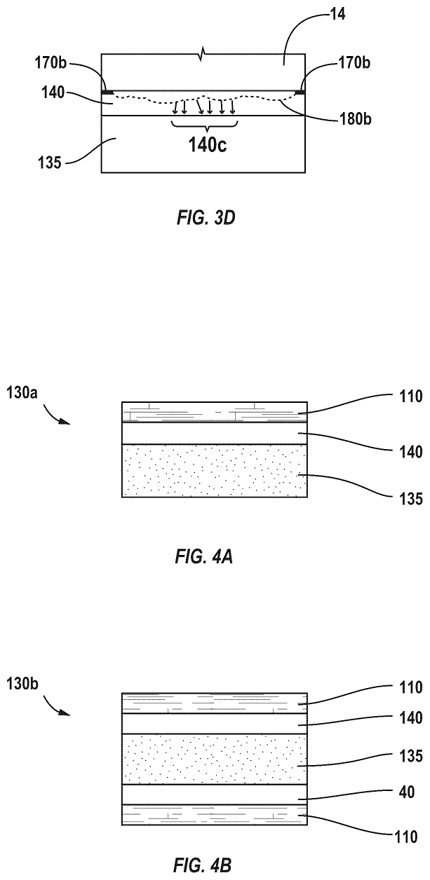

Examples of adhesive tape 130 may include “foaming tape” which may comprise a heat activated adhesive layer 140 incorporating “thermo expandable microspheres” 144 (as seen for example in FIG. 3A and others). The thermo expandable microspheres 144 may rely on a conversion of a material within the heat activated adhesive layer 140 from either a solid state or a liquid state to a gaseous state. In other words, foams may be made by creating a multiplicity of gas pockets within the heat activated adhesive layer 140. In some instances, a liquid “blowing agent” will form a gas at a high temperature that is encapsulated inside at least one of the thermo expandable microspheres 144.

Use of phase changes (such as thermo expandable microspheres 144) may provide advantages with respect to merely relying on the expansion or contraction due only to the material's CTE, which for polymers are on the order of about 200 ppm per° C. As an example, assuming a microsphere with a diameter of 50 μm made of a polymer with a CTE of 200 ppm per° C., then changing a temperature of the microsphere or other portion of the temperature sensitive adhesive, by 150° C. for release-the sphere or portion of material will change (grow or shrink) to a diameter or distance of 51.5 μm diameter. On the other hand, a material changing from solid or liquid state to gas may have changes in volume that are orders of magnitude larger. A thermo expandable microsphere 144 with a blowing agent may expand in a range of 4× to 60×.

Embodiments of adhesive tapes 130 may comprise at least one temperature activated release layer 140 or other suitable adhesive tapes 130 comprising at least one temperature activated release layer 140. The adhesive tape 130 and activated release layer 140 may comprise new or existing materials. Existing materials that have been used for unrelated and non-analogous applications that may be suitably used comprise Revalpha™ tape, including (i) No3195MS (38 μm base film thickness, 120° C. film release), (ii) RA-95LS (N) (100 μm base film thickness, 100° C. film release), and (iii) NO.3195VS (100 μm base film thickness, 170° C. film release), which are produced by Nitto Denko.

FIG. 2D further illustrates the first substrate 10 comprising a wafer (shown as a device wafer) being mounted with a top surface or front surface 21 having interconnect structures 125 disposed thereon, facing up over the adhesive tape 130, where the adhesive tape 130 is coupled to the support ring 120. The first substrate 10 comprising the wafer comprises components 14, as described herein, which may comprise a number of devices having the same or different device types based upon device functionality. The first substrate 10 comprising the wafer may have a thickness, t₁, in a range of 2-780 micrometers (μm), or less than 300 μm. In some embodiments, first substrate 10 comprising the wafer may have a thickness, t₁, of less than 150 micrometers (μm), or a thickness a thickness of from 2-150 μm, and in further embodiments a thickness of from 2-50 μm. A surface of backside 18 of the first substrate 10 comprising the wafer may directly contact temperature activated release layer 140.

FIG. 2E illustrates first substrate 10 comprising the wafer can be cut, diced, plasma diced, stealth diced, laser diced or singulated (such as with a saw or wafer cutting tool) into individual components 14 through saw streets 16 using one or more of a saw blade, a laser cutting tool, a plasma cutting tool, a scribe and break process, a partial trench then grind DBG process, and stealth laser dicing, to form a first substrate 10 comprising a diced wafer 11. According to some embodiments, the diced wafer 11 may comprise a singulated, reconstituted panel comprising components 14. In some instances, the components 14 will have a thickness, t₁, (shown in FIG. 2D for diced wafer 11) of between about 5 μm to about 150 μm for thin ground wafers, or about 100 μm to about 800 μm for thick ground wafers.

A first plurality of components 50 and a second plurality of components 60 may comprise a small component 14 footprint with edge lengths in a range of 0.10-3.0 millimeters (mm) and a thickness t₁, in a range of 1-925 micrometers (μm). This may include a full thickness of a standard semiconductor wafer. In some embodiments, the component 14 may be thin, having a thickness t₁, of −50 μm or less, or about 10 μm. In other instances, the first and second plurality of components 50, 60 may comprise components 14 that comprise a large die footprint with edge lengths of at least 3.0 millimeters (mm) up to 50 millimeters and a thickness t₁, in a range of 2-100 micrometers (μm). In cases where each the plurality of components contain multiple devices or other electronic or optical elements, such as with of fan-out wafer level processing or other methods that connect multiple devices into a single, large module 15, the module 15 may have footprint edge lengths that may be very large extending beyond 100 millimeters. However, in other instances where each of the plurality of components 50, 60 contain multiple devices, the components may also be much smaller with edge lengths below 100 millimeters to as small as 3.0 millimeters.

FIG. 2F-2I illustrate a pickup, single pickup, gang pickup, or pickup gang 200 picking up components 14 after at least one of a first portion 140a of the first adhesive tape 130 has been activated. More specifically, FIGS. 2F and 2G illustrate examples of a single pickup 200, while FIGS. 2H and 21 illustrate gang pickups 200. The component pickup tool 200 may operate with direct contact between the first plurality of components 50 and the component pickup tool 200 before the first plurality of components 50 are removed from the energy (or temperature) activated release layer 140.

FIG. 2F illustrates localized thermal release of a first component 14 of the first plurality of components 50 from the first portion 140a of the first adhesive tape 130, using a single pickup nozzle 200 and a thermal needle or probe 70 used opposite the pickup nozzle 200. In some instances, the thermal release or separation will result from the localized thermal release without a first general thermal change. In other instances, the overall thermal release (and pick up) may be sped up by a general thermal change (such as heating or cooling the entire wafer or thermal release layer 140 to a temperature near the activation or separation temperature), and then applying a localized thermal change of stimulus to complete the release. As such, in some instances the entire wafer 135 may be heated or cooled, with the next incremental or marginal heating or cooling occurring with the probe, pick-up, or gang 200.

The change in temperature (whether heating or cooling, and for ease of description is referred to generally as “heating”) may be general or local. General heating may be applied to an entirety of the first substrate 10 comprising a wafer, or applied to a plurality (or each) of the components 14 on the wafer 10 or substrate 12 severally, at a same time. Local heating may be less than general heating, and selectively applied to portions of the first substrate 10 comprising the wafer, module, reconstituted panel, or portions of the components 14 (including a plurality of components 14 that is less than an entirety of the first and second plurality of components 50, 60). The general and local heating may be applied separately or simultaneously to one or more of: a top or front surface 21 of the first substrate 10 comprising the wafer, a backside 18 or bottom surface of the wafer, or to both the front surface 21 and the backside 18 of the first substrate 10 comprising the wafer. For example, in one instance, local heating may be applied to the front surface 21 of the wafer 10 or components 14, and general heating (such as through a heated chuck or heated stage 80 as shown in FIG. 2G) may be applied to the backside 18 of the wafer or components 14, such as through a heated chuck or heated stage 80. In some instances, the general heating can bring the energy activated release layer 140 close to its activation energy (such as within a range of about 1-10° C., 5-10° C., or 10-20° C.), after which the localized heating brings the energy activated release layer 140 to a temperature (an activation temperature) where activation of a portion 140a of the layer occurs and upon completion of the activation, a reduction in adhesion has occurred so that the components 14 are ready to be removed.

As another example, with application for both single pickup and gang pickup 200, a thermal actuator could be used that that covers multiple components 14. More specifically, 10, 20, or any number of desirable components 14 could be heated and released together at a same time or as part of the same process, and then after heating the components 14 in the heated (or thermally activated) area, the components 14 could then picked up (whether one at a time or in a gang mode). As such, the number of components 14 being released at one time is different from (and need not be the same as) the number of components 14 being picked up.

In some instances, a ceramic shield or other insulative shield with open windows to allow for the select passage of heat may allow for localized or targeted energy or heating to occur while other shielded portions are not energy activated. When heated (and energy increases), the first portion 140a of the temperature activated release layer 140 expands, reducing its adhesion to the first plurality of components 50. In other instances, an actively cooled outer shield comprising one or more openings or interior windows may be used with a cooled probe 70 (or other energy source) that can pass through the openings. Active cooling could be by liquid-cooled coldplate (common in some wafer test applications), by Peltier device cooling (solid state), or in another suitable way. The selective activation by a dose of energy may be applied through a window of a mask, filter, screen, temperature-controlled device or shield with one or more windows. In some instances, a single window may be present, and the window may move with the thermal probe 70 to different areas of the first substrate 100, base film 135, or to different areas of different components 14.

In some instances, a lower temperature may cause the thermal release layer 140 less tacky, and then the pickup tool 200 applies a second cooling effect to pick up the individual or gang components 14. This same idea could apply to a thermal release layer 140 in which the tack decreases with heat (versus expanding microspheres) such that the temperature of the entire wafer 135 is elevated and then the pick-up tool 200 provides an addition amount of heat for pickup.

FIG. 2G illustrates localized thermal release with a single pickup nozzle 200, which is also heated. Localized heating for the component 14 being picked up is provided by the heated single pickup nozzle 200 and may be supplemented by additional local or general heating, such as a heated stage 80 or heated chuck, and a thermal needle 70 or other localized heating source, as shown.

A first portion 140a of the temperature activated release layer 140 may be activated, such as with a first dose of localized heat under a first portion (where the first portion may comprise one or more components 14) of the plurality of components 50 (although as described, alternatively cold could be used). The localized heat may be applied using a thermal needle, a laser, infrared lamp, visible light, a heated chuck, or other heating (or cooling) clement or source. UV light and exposure may be avoided and not used, contrary to approaches known in the prior art, relying instead on thermal energy to activate the temperature activated release layer 140.

FIG. 2H illustrates localized thermal release with a gang pickup nozzle 200 and several thermal needles 70 used opposite the pickup nozzle 200 to release a portion of the first plurality of components 50 from the first portions 140a of the temperature activated release layer 140.

FIG. 2I illustrates localized thermal release with a gang pickup nozzle 200, which is also heated. Localized heating for the component 14 being picked up is provided by heated gang pickup nozzle 200 and may be supplemented by additional local or general heating, such as a heated stage or heated chuck 80, and a thermal needle 70 or other localized heating source.

The removal of components 14 as illustrated in FIGS. 2F-2I may further comprise removal of a component 14 or a first portion of the first plurality of components 50 from the activated portion 140a of the release layer 140. Activation of the release layer 140 may occur based on a change in energy, including changes in temperature, which comprise both heating and cooling. The change in energy may occur all at once or at multiple times or in multiple stages, such as in two stages. The first stage may comprise the application of a first dose of localized energy (heating or cooling). The second stage may involve the application of a second dose of localized energy (heating or cooling), which is substantially equal to the first dose, or substantially different from the first dose. “Substantially” “about,” and “approximately,” as used herein, means a value that is identical to the stated value or a value that varies by a percent difference of 50% or less, 40% or less, 30% or less, 20% or less, 10% or less, 5% or less, or 1% or less.

The change in temperature (whether heating or cooling, and at times generically referred to herein as merely “heating” or “heat”) may be applied to one or more of the following: a top or front surface 21 of the first substrate 10 or wafer, a bottom surface or backside 18 of the first substrate 10 or wafer, or both. In a first instance, the release layer 140 is activated by heating, which may cause the release layer to expand. The heating process may involve applying a localized dose of heat to the release layer 140 or to portions of the release layer 140. The temperature activated release layer 140 may be heat activated at a temperature in a range of 50° C.-320° C. In a second instance, the release layer 140 is activated by cooling. The cooling process involves reducing the temperature of the release layer 140 to a range between −60° C. to 0° C. Cooling of the energy and temperature activated release layer 140 may causes contraction and release of the energy and temperature activated release layer 140. As discussed with respect to the following FIGs., after the first plurality of components 50 has been removed from the first portion 140a of the temperature activated release layer 140, a second portion 140b of the temperature activated release layer 140 is activated. This is followed by the removal of a second plurality (or portion) of components 60 from the activated second portion 140b of the release layer 140.

While a gang pickup 200 provides for moving multiple components 14 at a time, in some instances, a single component 14 at a time could be moved. For standard packaging (not making a reconstituted wafer 10 for FOWLP) moving only one component 14 at a time from a source wafer onto a package substrate or leadframe is common. In applications using gang pickup, some other temporary location may be needed for staging components, wherein one component at a time is transferred from the staging area or temporary location to the target substrate or leadframe. Alternatively, the pickup and placement head may be used to pick up a gang of components 14, but of the gang of components 14, only one of the gang is placed at a time. For instances in which a gang pickup is used for making a reconstituted FOWLP wafer, then the place operation or the pickup head is adjusted to account for the pitch of components on the wafer being smaller than the pitch of the components on the reconstituted wafer.

Single component pickup could also be used, although additional timing and space constraints could make this process more cumbersome and slower than desired. The coordination of the pickup 200 and thermal needle 70 or cooling probe 72 is often done serially, which means one pickup at a time, even when using multiple needles or probes simultaneously. The process may be sped up considerably, by using the gang pick up 200, and removing portions of, or a plurality of components 14 at a time. The pickup may follow activating a first portion 140a of the energy activated release layer 140. The first portion 140a of the temperature activated release layer 140 may be a selective portion of the energy activated release layer 140 that is less than all of the activated release layer 140, which differs from conventional release methods, such as blanket UV release, where an entirety of the release layer (or all of the release layer below the components) is activated all at one time.

FIG. 2J, continuing from FIG. 2I, illustrates that the first portion of the first plurality of components 50 can be removed from the first portions 140a of the temperature activated release layer 140 using gang or parallel pickup 200 after activation by thermal probes 70 disposed opposite the gang or parallel pickup 200. Second portions 140b of the temperature activated release layer 140 are depicted as having components 14 disposed thereon and staged for a subsequent pickup operation of the second plurality of components 60. The method as disclosed herein provides for removing the first plurality of components 50 and the second plurality of components 60 without an ejector pin or an ejector needle. Further, removing one or more components 14 from the energy activated release layer 140 may further comprise removing only known good components, and further comprising leaving any of the plurality of components 14 that are not known good components. Known good components may be first determined before removal from the thermal release layer 140. Known good components may be determined by passing a probe test or final test (such as when the components comprise packages).

FIG. 2K, continuing from FIG. 2J, illustrates that heat provided to a bottom side of the temperature activated release layer 140 may be provided by the heated chuck or stage, 80 disposed opposite a heated vacuum gang or heated parallel pickup 200. The first plurality 50 of components 14 can be removed from the first portion 140a of the temperature activated release layer 140 using the heated vacuum gang or heated parallel pickup 200.

The pickup 200 may comprise a vacuum pickup, an adhesive contact, or an electrostatic pickup, such as a Van Der Waals pickup. The vacuum pickup may comprise using suction or vacuum 210 to lift the first portion of components from the release layer 140. The vacuum 210 is applied to the front surface 21 of the components 14 opposite the temperature activated release layer 140. The reduced adhesion allows the components 14 to be lifted without damage. Alternatively, the pickup 200 may be a van der Waals pickup, using a surface to create temporary bonds to the front surface 21 of the components opposite the temperature activated release layer 140, based on van der Waals forces. The van der Waals forces are sufficient to lift the components 14 but then release them for transfer to another surface. As another alternative, the pickup 200 may be an adhesive contact pickup, using a low-tack, pressure-sensitive adhesive to temporarily bond to and lift the first and second portions of the first and second plurality of components 50, 60 from the release layer 140. The low-tack, pressure-sensitive adhesive is selected to bond to the components 14 with adequate force to lift them, then release them without residue or damage. In some instances, such as for FOWLP, components 14 may be placed on carrier tape that is stickier than the low-tack adhesive of the pickup tool 200. For placing components 14 on a die attach film for standard packages, the low-tack adhesive may be less feasible, depending on the die attach material being used. The electrostatic pickup may comprise inducing a charge difference between the component 14 and the pickup tool 200, which allows an electrostatic field to be used in lifting and transferring the component 14, such as from one first substrate 10, wafer, reconstituted panel, or module, to another.

The time for release of a portion of the first plurality 50 of components 14 from the activated first portion 140a of the release layer 140 may be in a range of 0.001 to 5.0 seconds, or 0.25 to 2 seconds. In some instances, a fast or high-speed pick up may be accomplished in a time in a range of 10 milliseconds (ms) to 250 ms. Conventional needle-based die pickups typically occur in a range of 0.06 to 1 second, but are however, always limited to a single die pick-up.

The amount of force needed to pick up a portion of the first plurality 50 of components 14 by the pickup tool 200 may be reduced by 50-99%, or at least 50% less than, an amount of force needed to pick up the components 14 with an ejector pin or ejector needle and without the temperature activated release layer 140. Furthermore, an additional advantage is reducing the negative effect of the ejector needle applying a relatively concentrated force to the backside of the module 15 or component 14, which can crack the chips during pickup (especially when backgrind scratches are present as stress concentrators). For example, a pickup force from the pickup gang 200 (as well as the heating mechanism) may comprise a “floating z” or have a “soft touch feature” which performs its function with little or very little applied force, which could nonetheless damage and crack thin components 14. As an example, the pickup force from the pickup gang 200 on a component 14 (including for components 14 comprising a size of about 300-400 μm) may be in a range of 0.5-1.5 grams-force (g-f), 0.72-1.2 g-f, or about 0.89 g may be used. The reduced force, together with the possibility of an increased number of components 14 transferred at a time, results in significantly faster, higher yield component transfer.

Traditionally, components 14 have been ejected from an adhesive tape, carrier, or ring, serially using an ejector needle. An ejector needle applies force to the backside of each individual component 14 to overcome the adhesion holding it in place, such as to the tape, and eject the component 14. However, conventional use of ejector needles is a delicate and often difficult process resulting in a slow, tedious process prone to quality concerns with cracking when handling many components, such as: small components, large components which are very thin or large modules which are thin.

The current approach, using thermal release layers 140, including thermal ejectors (whether hot or cold) without ejector needles is a novel new approach. In some instances, a thermal ejector may be used in place of ejector needles. In other instances, an ejector needle with less force could be used. In yet other instances, a thermal needle could provide a thermal function while also having movement to act also as an ejector needle-but one that applies much less force than conventional The thermal ejector applies localized heat (or cold) to a first portion 140a and a second portion 140b of the temperature activated release layer 140 disposed under portions or pluralities of components 14 to reduce adhesion over an area corresponding to the first portion 140a and the second portion 140b, allowing a single component 14 to be released, or multiple components 14 to be released in parallel, or at a same time, such as with gang pickup 200. The thermal ejector may be a thermal needle, using a heated probe 70 to trace a pattern on the release layer 140, or a thermal plate with selective heating elements, or other suitable device and method. When dealing with cold release, chucks that chill may be used, such as with a thermal mask to produce or convey localized cooling. Similarly, liquid nitrogen, alcohol dry ice bath, Peltier device, or liquid cooled chucks for cooling or other suitable method may also be used. When the adhesion under the first plurality 50 or second plurality 60 of components 14 is reduced by thermal treatment (such as heating or cooling) of the release layer 140, a portion of components 14, including the first plurality 50 or second plurality 60 of components, can be removed by a gang pickup 200 in a single operation. In some instance, the gang pickup 200 may move on the order of 10s, 100s, 1,000s, or 10,000s or more components 14 at a time, based on the gang or tool limitations.

As an alternative, the thermal ejector may impart a temperature change (cold or heat) without physical contact to the temperature activated release layer 140 or components 14. Radiant heat, laser energy, or other contactless heating (or cooling) methods may be used to activate the release layer 140 under pluralities of components 14 so they can be picked up in parallel by a gang pickup or by single pickup. By using contactless heating (or cooling), the possibility of damage to the components 14 by an ejector needle or other contacting method is eliminated. In other instances where an ejector needle is still used, less force is needed due to the change in adhesion resulting from the change in temperature and affects on the temperature activated release layer 140.

The thermal ejector, whether contact or contactless, allows groups of components to be released and picked up in parallel or singly, significantly increasing the speed of transfer from the adhesive tape 130 to another substrate or surface. The thermal ejector may be used alone or in combination with ejector needles for some components 14. The thermal ejector enables high throughput transfer of small components 14, without damaging components 14 that might otherwise be easily damaged.

The present method, using support ring or carrier 120 may have both heating or cooling regions and insulating regions or temperature-controlled regions that correspond (or are mapped) to the positions of groups or portions of components 14 on the adhesive tape 130 (and are opposite the active pick up regions). The heating (or cooling) regions are selectively activated to change the temperature activated release layer 140 under the corresponding groups or portions of components 14, while the insulating regions remain less thermally active. This allows different groups or portions of components 14 to be released at different times as needed for effective transfer.

The present method is particularly advantageous for handling and transferring thin or fragile components 14 that are easily damaged by traditional ejection methods. By using a temperature activated release layer 140 (and even an ejector or thermal ejector), the components 14 can be released and picked up with minimal contact or force, reducing the possibility of damage. For components 14 with functional layers on both sides, such as an active or passive silicon interposer with through silicon vias (TSV), the temperature activated release layer 140 allows for precision transfer without damage to either side.

The present method enables a valuable new approach for transferring both small and large, thin components in the industry. Traditionally, both small and large components 14 have been difficult to transfer using classic needle ejection without damage, and thin components 14 are easily broken during handling and transfer or result in slow die attach machine throughput. The temperature activated release layer 140 overcomes these challenges by allowing groups of small, large, thin, and even fragile components 14 to be released and picked up in parallel, or singly, with minimal contact, force, and possibility of damage.

The present method may be used for transferring and handling small components 14, or a first plurality 50 of small components, with an edge length 14a (width or length) less than 3 mm, as well as large components 14 with an edge length 14a greater than 3 mm and with a thickness less than 300 μm, or thin components 14 with a thickness in a rage of 10-150 μm, or very thin components 14 in a thickness range of 1-50 μm. The temperature activated release layer 140 and thermal ejector enable high throughput, high yield transfer of components that have previously been difficult or impossible to transfer effectively. This capability could significantly improve manufacturing processes and yields for advanced electronic assemblies using the latest small or large thin, and fragile components 14.

After removal of the first portion of components 14, as shown in FIGS. 2F to 2K, a second portion of a second plurality 60 of components 14 may be removed in a similar fashion, as depicted in FIGS. 2L to 2M. FIG. 2L illustrates where first portions 140a of the temperature activated release layer 140 no longer have a component 14 disposed thereon, and the second plurality 60 of components 14 are next to be picked up (after activation of release layer 140) by the heated vacuum gang or heated parallel pickup 200 from second portions 140b of the temperature activated release layer 140. 2L depicts activating the second portion 140b of the temperature activated release layer 140 after removing the first plurality 50 of components 14, and removing the second plurality of components 60 from the second portion 140b of the temperature activated release layer 140 after activating the second portion 140b of the temperature activated release layer 140. After the second portion of the second plurality 60 of components 14 are removed, all components 14 may be removed. In addition, any remaining portions of components 14 may be removed in any desired number of subsequent portions.

FIG. 2M shows where one or more components 14 are disposed within a first portion of a first plurality 50 of modules 15 atop the temperature activated release layer 140. Similar to FIG. 2L, first and second portions, 140a and 140b, respectively, may be heat activated such that modules 15 may be easily removed.

FIG. 3A provides additional detail for when the temperature activated release layer 140 comprises thermo expandable microspheres 144. According to some embodiments, the temperature activated release layer 140 may be formed as a thermal release adhesive comprising thermo-expandable capsules or microspheres that expand when activated by heat.

When heated, a blowing agent inside the microspheres 144 is converted to a gas causing the microspheres 144 to rapidly expand, changing the surface topology of the adhesive layer and the area of contact between the adhesive and the component 14 (or adherend) and significantly reducing its adhesion, as further illustrated by FIGS. 3B to 3D. The temperature activated release layer 140, comprising thermo expandable microspheres 144 has a reduced or weakened bond and may be more inclined to peel away from the components 14, allowing them to be picked up or removed easily by the single or gang pickup 200. The adhesive tape 130, comprising the temperature activated release layer 140 having thermo expandable microspheres 144, provides a simple, low-cost method for removal of components 14 which are thin, fragile and prone to breakage.

To maximize the effectiveness of the temperature activated adhesive release layer 140, it may be configured with the heat expandable microspheres 144 at the interface with the components 14, rather than at the interface with the support ring or carrier 120. When the microspheres 144 are located at an interface between the release layer 140 and the component 14 and heated, they expand, creating gaps between the temperature activated release layer 140 and components 14, rapidly reducing adhesion at the interface.

In some embodiments, a base film 135 may be disposed between the microspheres 144 and the support ring or carrier 120, the base film 135 comprising a stiff material that does not significantly deform when the microspheres 144 in the adhesive expand. A material like polyester (PES) may be used. The stiff, thermo expandable microspheres 144 provide a solid base for the temperature activated release layer 140 so that microsphere expansion generates maximum force at the interface with the components 14, rather than being dissipated through deformation of the base film 135 or support ring or carrier 120.

FIGS. 3B to 3D provide additional detail for when the temperature activated release layer 140 may be activated by cold, or a decrease in temperature, which can cause the thermal release layer 140 (such as a polymer matrix) to stiffen and contract and a contracting portion 140c of the thermal release layer 140 to locally pull away from the component 14 after having been treated or affected by a cooling probe 72. FIG. 3B illustrates where the temperature activated release layer 140 comprises a contracting portion 140c. In some instances, the thermal release layer 140, comprising the contracting portion 140c, may comprise liquid crystalline elastomers (LCEs) that undergo liquid crystal phase change, or electrostatic anisotropic hydrogels (EAHs) that undergo changes in polymer intrachain electrostatic interactions, or other suitable substances that contract or stiffen with changes in temperature. FIG. 3B further depicts a bond 170a, representing a contact interface between a backside 18 or back surface of the component 14 and the temperature activated release layer or thermal release layer 140. FIG. 3B further shows a first surface topography 180a of a top surface of the thermal release layer 140. As may be seen in FIG. 3B, cooling has not been applied by the cooling probe 72. As such, the bond 170a fully covers the backside 18 or back surface of the component 14 and the surface topography 180a of the thermal release layer 140 substantially conforms to the backside 18 or back surface of the component 14. Accordingly, the bond 170a and surface topography 180a are closely aligned or adjacent to one another. As may be seen in FIG. 3C, cooling has been applied by the cooling probe 72 (as shown in FIG. 3B), causing the contracting portion 140c of the thermal release layer 140 to detach from the backside 18 or back surface of the component 14, causing a reduced bond 170b between the component backside and the thermal release layer 140. The reduced bond 170b causes a reduction in adhesion of the thermal release layer 140 to the components 14 and the reduced bond 170b and and a second surface topography 180b have become separated. FIG. 3D illustrates a detail view of FIG. 3C, showing the reduced bond 170b remaining at the outermost edges of component 14, and the second surface topography 180b which is increased over the first surface topography 180a by cooling of the contracting portion 140c upon reduced temperature and detachment of the thermal release layer 140 from the component backside 18.

FIG. 4A provides additional detail for a single adhesive layer tape 130a comprising a thermal release adhesive 140 that may be heat activated, including exemplary layers and layer types. A liner, protective layer, or shield layer 110 may be disposed above (or adjacent) the thermal release adhesive or temperature activated release layer 140 for protection of the thermal release layer 140. The liner 110 is protective during tape storage, but it is removed prior to the tape being applied to the adherend, wafer, or components 14. The base film 135 provides a rigid base from which the thermal release layer 140 disposed atop the base film 135 expands or contracts.

Similar to FIG. 4A, FIG. 4B provides additional detail for a multi adhesive layer tape 130b comprising a thermal release layer 140 that may be temperature or heat activated, including exemplary layers and layer types. The multi adhesive layer tape 130b comprises the thermal release layer 140, and may further include below (or at a first side) a base film 135, a base adhesive 40, and a liner 110 or shield that may be removed to expose the base adhesive 40. The multi adhesive layer tape 130b may further include above (or at a second side opposite the first side) the thermal release layer 140 a liner 110 or shield that may be removed to expose the thermal release layer 140. In some instances, multiple layers of thermal release layer 140 or zones of thermal release layer 140 may be used so as to provide discrete or non-contiguous zones of temperature sensitive or thermal release adhesive 140. In some instances, multiple layers or zones of thermal release adhesive 140 may be activated at different temperatures, so that various zones may thermally activated at different times and under different conditions.

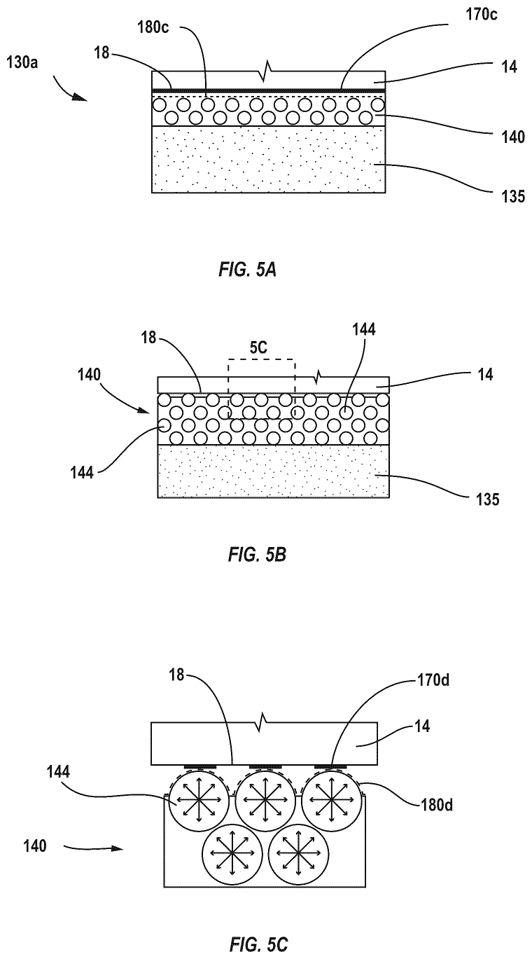

FIGS. 5A-5C provide additional detail regarding the mechanics of a single adhesive layer tape 130a comprising a thermal release layer 140 operating to separate from an adherend or component 14. More specifically, FIG. 5A provides additional detail for a thermal release layer 140 comprising a thermally sensitive adhesive layer comprising thermo expandable microspheres 144 (as shown here and in FIG. 5B) or capsules that are disposed between a base material 135 and an adherend or backside 18 of component 14. FIG. 5A illustrates a bond 170c between the backside 18 of component 14 and the thermal release layer 140 prior to heating or cooling of the thermal release layer 140. Further depicted is a surface topography 180c of a top surface of the thermal release layer 140. Prior to heating or cooling of the thermal release layer 140, the bond 170c and surface topography 180c may be closely aligned or adjacent to one another.

FIG. 5B provides additional detail for when the single adhesive layer tape 130a comprising a temperature activated release or adhesive layer 140 is temperature activated and expands with a dose of localized heat under a first portion of the base material to cause a first portion 140a (as depicted in FIGS. 2F to 2M, 3A and others) of the thermal release layer 140 to expand. Expansion can be driven by a phase change of the thermo expandable microspheres 144, such as from a solid state or a liquid state to a gaseous state, to create a plurality of gas pockets in the thermal release adhesive or layer 140. FIG. 5C is a detail view of FIG. 5B, showing a bond 170 In some instances, a liquid “blowing agent” will form a gas at a high temperature that is encapsulated inside a microsphere 144, to reduce a bond between the temperature activated release layer 140 and the adherend, such as a portion of the plurality of components 14.

FIG. 5C provides a close-up view of a portion of FIG. 5B, with the microspheres 144 within the thermal or temperature activated release layer 140 expanding to significantly reduce contact area (and therefore adhesion) as represented by reduced bond 170d between the adherend or backside 18 of component 14 and a portion of the temperature activated release layer 140. Further depicted is surface topography 180d which is changed from that of surface topography 180c by the application of heat. The changes in thermal release layer 140, as depicted in FIGS. 3B to 3D and 5A to 5C, whether resulting from application of heat or cooling or both, provide a change in surface topography 180a to 180d, and a change in the bond 170a to 170d, of the temperature activated release layer 140 such that adhesion is reduced.

FIG. 6A, similar to FIG. 4A, provides additional detail for a single adhesive layer tape 130c comprising a thermal release layer 140 that may be cold activated, including exemplary layers and layer types. As for FIG. 4A, FIG. 6A shows a liner, protective layer, or shield layer 110 may be disposed above (or adjacent) the thermal release adhesive or temperature activated release layer 140 for protection of the thermal release layer 140, and may be removed prior to the tape being applied to the adherend, wafer, or components 14. The base film 135 provides a rigid base from which the thermal release layer 140 disposed atop the base film 135 expands or contracts.

FIG. 6B, similar to FIG. 4B, provides additional detail for a multi adhesive layer tape 130d comprising a thermal release layer 140 that may be cold activated, including exemplary layers and layer types. The multi adhesive layer tape 130d comprises the thermal release layer 140, and may further include below (or at a first side) a base film 135, a base adhesive 40, and a liner 110 or shield that may be removed to expose the base adhesive 40. The multi adhesive layer tape 130b may further include above (or at a second side opposite the first side) the thermal release layer 140 a liner 110 or shield that may be removed to expose the thermal release layer 140. In some instances, multiple layers or zones of thermal release adhesive 140 may be activated at different temperatures, so that various zones may thermally activated by heating or cooling at different times and under different conditions. FIG. 6C, similar to FIGS. 6A-6B, illustrates the multi adhesive layer tape 130d in which the base adhesive 40 is bonded to the base film 135 above and to the metal carrier or support ring 120 below. Further, the thermal release layer 140 can be any of the types of thermal release layers previously described.

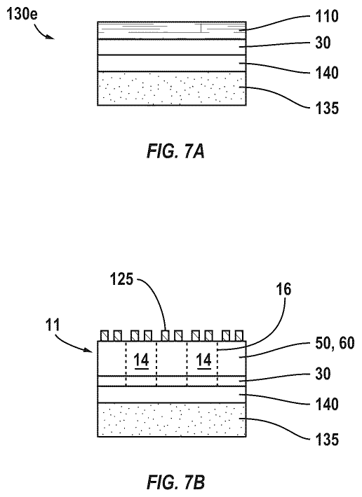

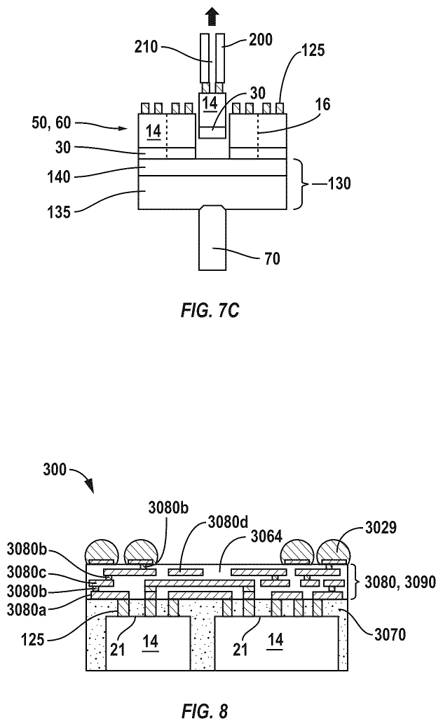

FIGS. 7A-7C illustrate another aspect of the disclosure in which a Dicing Die Attach Film (Dicing DAF or DDAF) 30 is used. Rather than place a die attach material on a package substrate or leadframe (e.g., a die attach paste), and then placing the components 14 onto the die attach material, a DAF can be applied to the backside 18 of the first substrate 10 or wafer. In some instances, a first substrate or wafer 10 with DAF 30 on the backside 18 can be applied to a dicing tape (not shown) and then singulated. In other instances, a DDAF 30 which performs the functions of both the DAF and the dicing film can be used, so that separate DAF and dicing tape and both functions are combined into one tape. The thermal release layer 140 allows separation of the DAF 30 from the thermal release layer 140, and allows the DAF 30 to stay with the components 14, as illustrated in FIGS. 7A-7C. DDAF 30 may be advantageous for thin memory die or components 14 going into stacked chip packages (e.g., NAND).

FIG. 7A illustrates an adhesive tape 130e comprising a Dicing Die Attach Film Adhesive 30 (or DDAF), disposed between, and contacting the liner 110 and the thermal release layer 140.

FIG. 7B, continuing from FIG. 7A, shows the adhesive tape 130e with the liner 110 removed and a first substrate or wafer 10 coupled to the DAF or DDAF layer 30. FIG. 7A further shows the first substrate or wafer 10 after singulating the first substrate or wafer 10 into individual components 14 to form a first or second plurality of components, 50, 60 respectively. The singulation could be accomplished by any suitable singulation or dicing process.

FIG. 7C, continuing from FIG. 7B, shows the pickup tool 200 removing a component 14 (with the DAF 30 attached to the component 14) from adhesive tape 130 comprising the thermal release layer 140. FIG. 7C further includes a thermal probe 70, which may optionally be used with an optionally headed pickup tool 200. The heated probe 70 may comprise a bottom probe that provides heat and applies a small upward force to act as a low-force ejector for the plurality of components 14. As used herein, a small upward force means a force in a range of about 0.5-50 g-f. While described here for a heated probe or thermal needle 70, FIG. 7C may also be used with a cooling probe 72 as earlier described but not shown.

For instances in which a thermal needle or heated probe 70 is used for localized heating, the heat from the probe 70 will need to travel through the base film 135 (e.g., a polymer or polyester material), where the base films 135 are generally not good thermal conductors. As such, an improved or enhanced thermally conductive base film 135 may be employed to improve heat transfer through the base film 135 to the temperature activated release layer 140. The base film 135 may be thermally enhanced by introducing inorganic, thermally conductive particles into the polymer (which may operate in a way similar to filler in mold compound). For example, Lumirror™ is a product offered by Toray which is a PET film (in the polyester family) with thermal filler that is 2.5 times the thermal conductivity of standard PET film. Using thermally conductive particles with the base film 135, as well as the temperature activated release layer 140, can improve the time and efficiency with which heat is transferred through the tapes or films to augment the reduction in adhesion upon application of heating or cooling.

In other instances, the temperature activated release layer 140 may comprise an array of bi-metal or other suitable elements that deform as a result of a temperature change, such as doming or popping up when heat is applied. As such, rather than the cumulative effect of a many smaller microspheres 144 used to create a reduction in adhesion, a larger macro change could be relied on to produce the reduction in adhesion with components 14. Additionally, a change in a physical shape of the carrier or carrier surface (rather than a distinct layer) could create a reduction in adhesion as a result of a thermal change, an electrical stimulus, or other stimulus. With such a physical change, a standard pressure sensitive adhesive could be used in place of the temperature activated release layer 140. In instances where expensive carriers are used and reused, the adhesive would be replaced for each reuse of the carrier.

FIG. 8 depicts an electronic assembly or package 300 comprising a build up interconnect structure including routing layers 3080a to 3080d for forming redistribution layers (RDL), conductive layers, pads, fanouts and/or LGA pads for flip chip bonding and to allow connectivity from one conductive layer to another between dielectric layers 3064. Components 14 as part of the electronic assembly 300 may have the features as disclosed herein and may be assembled according to the disclosed methods for transfer of thin or fragile components 14.

While this disclosure includes a number of embodiments in different forms, the particular embodiments presented are with the understanding that the present disclosure is to be considered as an exemplification of the principles of the disclosed structures, devices, methods, and systems, and is not intended to limit the broad aspect of the disclosed concepts to the embodiments illustrated. Additionally, it should be understood by those of ordinary skill in the art that other structures, manufacturing devices, and examples could be intermixed or substituted with those provided. In places where the description above refers to particular embodiments, it should be readily apparent that a number of modifications may be made without departing from the spirit thereof and that these embodiments and implementations may be applied to other technologies as well. Accordingly, the disclosed subject matter is intended to embrace all such alterations, modifications and variations that fall within the spirit and scope of the disclosure and the knowledge of one of ordinary skill in the art. As such, it will be evident that various modifications and changes may be made thereto without departing from the broader spirit and scope of the inventions as set forth in the appended claims. The specification and drawings are, accordingly, to be regarded in an illustrative sense rather than a restrictive sense.

Many additional implementations are possible. Further implementations are within the CLAIMS.

What is claimed is:

1. A method of transferring components for an electronic assembly, the method comprising:
providing an adhesive tape coupled to a support ring, wherein the adhesive tape comprises a temperature activated release layer;
coupling a wafer to the temperature activated release layer;
singulating the wafer into a plurality of components, wherein a thickness of the wafer comprises a thickness less than 150 micrometers (μm);
activating a first portion of the temperature activated release layer with a first dose of localized heat under a first plurality of components to cause the first portion of the temperature activated release layer to expand and reduce a bond between the first portion of the temperature activated release layer and the first plurality of components;
removing the first plurality of components from the first portion of the temperature activated release layer using a pickup tool;
activating a second portion of the temperature activated release layer with a second dose of localized heat under a second plurality of components to cause the temperature activated release layer to expand and reduce a bond between the temperature activated release layer and the second plurality of components after removing the first plurality of components; and
removing the second plurality of components from the second portion of the temperature activated release layer.

2. The method of claim 1, wherein the temperature activated release layer is heat activated at a temperature in a range of 50° C. to 320° C.

3. The method of claim 1, wherein the plurality of components comprises one or more of a semiconductor device, an active device, an analog device, a passive device, a memory die, a semiconductor chip, a chiplet, a power device, a transistor, an RF device, an RF switch, a high-electron-mobility transistor (HEMT) device, a bridge die, a dummy die, LEDs, solar cells, a laser device, optical amplifiers, photo diodes, and other micro-electronic and micro-optoelectronic devices, a MEMS, a sensor, a VCSEL, RFID components, a package, and a fan-out wafer level package (FOWLP).

4. The method of claim 1, further comprising forming the temperature activated release layer as a layer as part of an adhesive tape.

5. The method of claim 1, further comprising forming the temperature activated release layer as a thermal release adhesive comprising thermo expandable capsules or microspheres that expand when activated by heat.

6. The method of claim 1, wherein removing the first plurality of components and the second plurality of components occurs without an ejector pin or an ejector needle.

7. The method of claim 6, wherein the pickup tool uses an amount of force that is at least 50% less than what would be used for pickup with an ejector needle and without a temperature activated release layer.

8. A method of transferring components for an electronic assembly, the method comprising:
providing an energy activated release layer;
coupling a wafer to the energy activated release layer;
singulating the wafer into a plurality of components;
activating a first portion of the energy activated release layer with a first change in temperature;
removing a first portion of the plurality of components from the first portion of the energy activated release layer;
activating a second portion of the energy activated release layer with a second change in temperature after removing the first portion of the plurality of components; and
removing a second portion of the plurality of components from the second portion of the energy activated release layer.

9. The method of claim 8, wherein the first portion of the plurality of components comprise modules or packages, and the wafer comprises a reconstituted panel.

10. The method of claim 8, wherein the plurality of components comprises one or more of a package, a module, a semiconductor device, an active device, an analog device, a passive device, a memory die, a semiconductor chip, a chiplet, a power device, a transistor, an RF device, an RF switch, a high-electron-mobility transistor (HEMT) device, a bridge die, a dummy die, LEDs, solar cells, a laser device, optical amplifiers, photo diodes, and other micro-electronic and micro-optoelectronic devices, a MEMS, a sensor, a VCSEL, and RFID components.

11. The method of claim 8, further comprising forming the energy activated release layer as a layer within an adhesive tape.

12. The method of claim 8, wherein activating the first portion of the energy activated release layer with a first change in temperature further comprising heating the first portion of the energy activated release layer to cause expansion of the first portion of the energy activated release layer.

13. The method of claim 8, further comprising activating z thermo expandable capsules or microspheres by exposing the thermo expandable capsules or microspheres to energy in the form of heat.

14. The method of claim 8, further comprising removing the first portion of the plurality of components and the second portion of the plurality of components without using an ejector pin or an ejector needle.

15. The method of claim 8, wherein activating the first portion of the energy activated release layer with a first change in temperature further comprises cooling the first portion of the energy activated release layer to cause a reduction in adhesion of the first portion of the energy activated release layer.

16. The method of claim 15, wherein a reduction in adhesion results from contraction of the first portion of the energy activated release layer.

17. The method of claim 15, wherein applying a first dose of localized heat comprises: applying bottom localized heat by a probe, applying top localized heat provided by a pickup tool, or both.

18. A method of transferring components for an electronic assembly, the method comprising:
providing a wafer coupled to an energy activated release layer;
singulating the wafer into a plurality of components;
activating a first portion of the energy activated release layer; and
removing a first component of the plurality of components from the first portion of the energy activated release layer.

19. The method of claim 18, wherein the plurality of components comprises one or more of a module, a package, a semiconductor device, an active device, an analog device, a passive device, a memory die, a semiconductor chip, a chiplet, a power device, a transistor, an RF device, an RF switch, a high-electron-mobility transistor (HEMT) device, a bridge die, a dummy die, LEDs, solar cells, a laser device, optical amplifiers, photo diodes, and other micro-electronic and micro-optoelectronic devices, a MEMS, a sensor, a VCSEL, and RFID components.

20. The method of claim 18, further comprising forming the energy activated release layer as a layer within an adhesive tape.

21. The method of claim 18, wherein a reduction in adhesion comprises a change of surface topography and a contraction of the energy activated release layer due to cooling of the first portion of the energy activated release layer.

22. The method of claim 18, wherein a probe provides heat and applies a small upward force to act as a low-force ejector for the plurality of components.

23. The method of claim 18, further comprising:
activating a second portion of the energy activated release layer after removing the first plurality of components; and
removing a second plurality of components from the second portion of the energy activated release layer after activating the second portion of the energy activated release layer.

24. The method of claim 18, wherein removing the component from the energy activated release layer further comprises removing a known good component, and further comprising leaving any of the plurality of components that are not known good components.
